(19) United States
(12) Patent Application Publication
(10) Pub. No.: US 2026/0136653 A1
(43) Pub. Date: May 14, 2026

(54) Gate Stacks for Stacked Device Structures and Methods of Fabrication Thereof

(71) Applicant: Taiwan Semiconductor Manufacturing Company, Ltd., Hsin-Chu (TW)

(72) Inventors: Cheng-Ming LIN, Kaohsiung City (TW); Tsung-Kai CHIU, Hsinchu County (TW); Wei-Yen WOON, Taoyuan City (TW); Szuya LIAO, Hsinchu (TW)

(21) Appl. No.: 19/171,823

(22) Filed: Apr. 7, 2025

Related U.S. Application Data
(60) Provisional application No. 63/719,936, filed on Nov. 13, 2024.

(51) Int. Cl. H10D 84/85; H10D 30/00; H10D 30/01; H10D 30/43; H10D 62/10; H10D 64/68; H10D 84/01

(52) U.S. Cl. CPC H10D 84/851; H10D 30/014; H10D 30/0191; H10D 30/43; H10D 30/502; H10D 62/102; H10D 62/121; H10D 64/685; H10D 84/0177; H10D 84/0179; H10D 84/0181; H10D 84/856

(57) ABSTRACT

Gate stacks for stacked device structures, such as stacked transistors, and methods of fabrication thereof are disclosed. An exemplary method includes forming a semiconductor layer stack over a substrate. The semiconductor layer stack includes a first semiconductor layer disposed over a second semiconductor layer. The method further includes forming a first type metal gate layer around the second semiconductor layer. The method further includes, after forming an aluminum-containing isolation layer over the first type metal gate layer, forming a second type metal gate layer around the first semiconductor layer and over the aluminum-containing isolation layer. In some embodiments, the method further includes removing a native metal oxide layer from over the first type metal gate layer before forming the aluminum-containing isolation layer. In some embodiments, removing the native metal oxide layer from over the first type metal gate layer includes performing a chlorine-based gas treatment.

This is a non-provisional application of and claims benefit of U.S. Provisional Patent Application Ser. No. 63/719,936, filed Nov. 13, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the semiconductor industry progresses into advanced IC technology nodes in pursuit of higher device density, higher performance, and lower costs, challenges from both a fabrication perspective and a design perspective have led to stacked transistor configurations, which have presented a new set of challenges. Improved gate fabrication techniques for stacked device structures, such as complementary transistor stacks, are thus needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a cross-sectional view of a stacked device structure, in portion or entirety, according to various aspects of the present disclosure.

FIG. 1B and FIG. 1C are cross-sectional views of the stacked device structure of FIG. 1A, in portion or entirety, according to various aspects of the present disclosure.

FIG. 2 is a flow chart of a method for fabricating gate stacks of transistors of a stacked device structure, such as gate stacks of transistors of the stacked device structure of FIGS. 1A-IC, according to various aspects of the present disclosure.

FIGS. 3A-3K are cross-sectional views of a stacked device structure, such as the stacked device structure of FIGS. 1A-IC, in portion or entirety, at various fabrication stages associated with the method of FIG. 2, according to various aspects of the present disclosure.

FIGS. 4A-4K are cross-sectional views of another stacked device structure, such as the stacked device structure of FIGS. 1A-IC, in portion or entirety, at various fabrication stages associated with the method of FIG. 2, according to various aspects of the present disclosure.

FIG. 5 is a flow chart of another method for fabricating gate stacks of transistors of a stacked device structure, such as gate stacks of transistors of the stacked device structure of FIGS. 1A-IC, according to various aspects of the present disclosure.

FIGS. 6A-6H are cross-sectional views of another stacked device structure, such as the stacked device structure of FIGS. 1A-IC, in portion or entirety, at various fabrication stages associated with the method of FIG. 5, according to various aspects of the present disclosure.

FIG. 7 is a cross-sectional view of another stacked device structure, such as the stacked device structure of FIGS. 1A-IC, in portion or entirety, that may be fabricated according to the method of FIG. 5, according to various aspects of the present disclosure.

FIG. 8 is a plot of experimental results associated with gate isolation layers, such as those that may be implemented in the stacked device structure of FIGS. 1A-IC when fabricated by the method of FIG. 5, according to various aspects of the present disclosure.

FIG. 9, FIG. 10, and FIG. 11 are cross-sectional views of different stacked device structures, in portion or entirety, which may be fabricated using the method of FIG. 1 and/or the method of FIG. 5, according to various aspects of the present disclosure.

### DETAILED DESCRIPTION

The present disclosure relates generally to stacked device structures, such as transistor stacks having n-type transistors and p-type transistors (i.e., complementary field effect transistors (CFETs)), and more particularly, to gate stacks for stacked device structures.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Stacked device structures provide further density reduction for advanced integrated circuit (IC) technology nodes (particularly as they advance to 3 nm (N3) and below), especially when the stacked device structures include multigate devices, such as fin-like field effect transistors (FinFETs), gate-all-around (GAA) transistors including nanowires and/or nanosheets, other types of multigate devices, etc. Stacked device structures vertically stack devices, such as transistors. For example, a transistor stack may include a first transistor (e.g., a top transistor) disposed over a second transistor (e.g., a bottom transistor). The transistor stack may provide a complementary field effect transistor (CFET) when the first transistor and the second transistor are of opposite conductivity type (i.e., an n-type transistor and a p-type transistor).

The present disclosure is generally directed to gate stacks for stacked device structures, such as stacked transistors, and methods of fabrication thereof. For example, methods for fabricating dual work function metal (DWFM) gate stacks are disclosed that may improve device performance, for example, by reducing resistance and/or improving isolation.

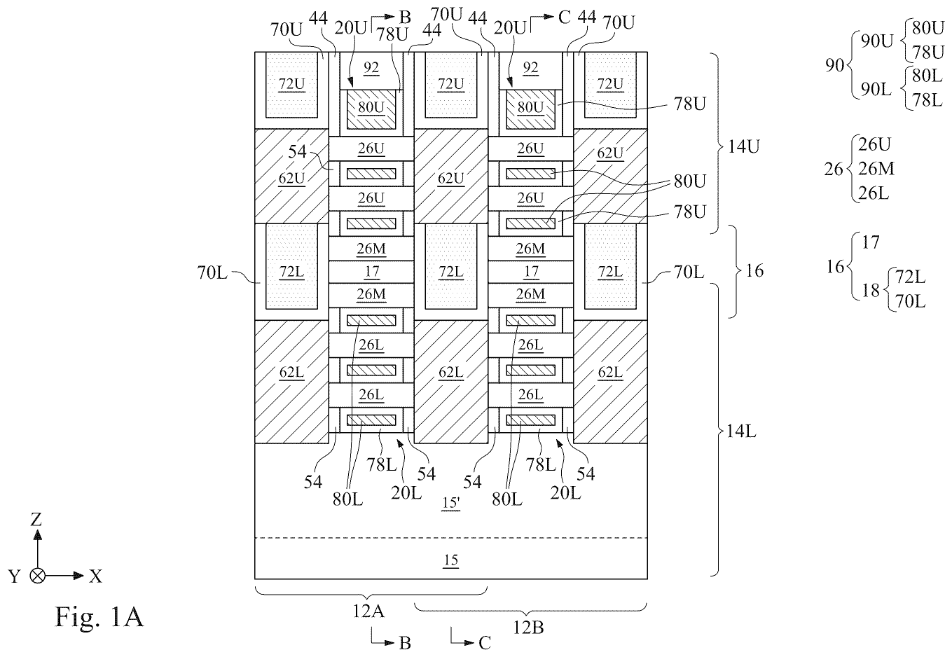

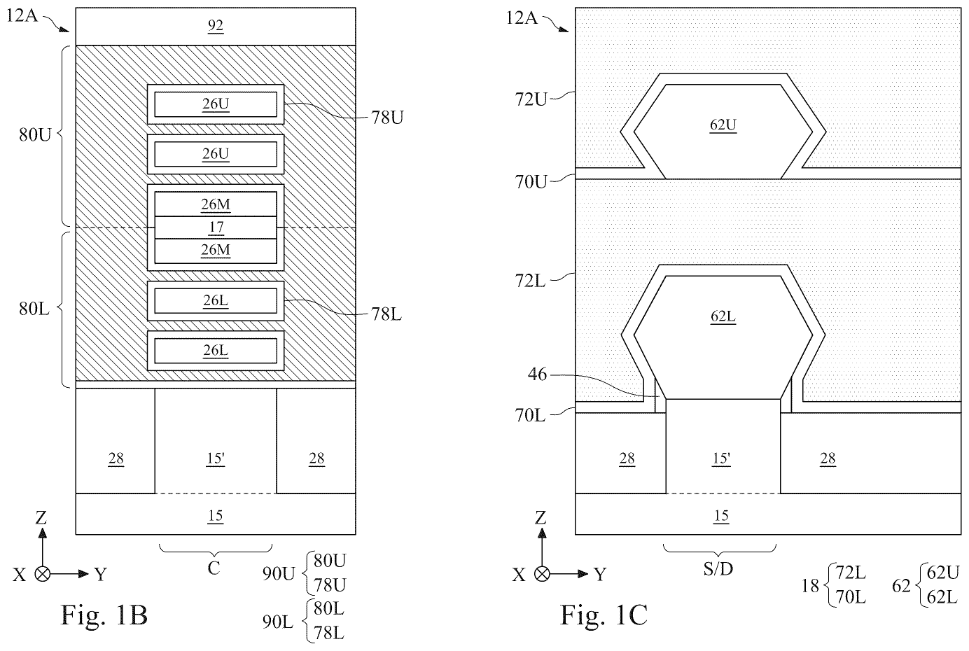

FIG. 1A is a cross-sectional view of a stacked device structure 10, in portion or entirety, according to various aspects of the present disclosure. FIG. 1B and FIG. 1C are cross-sectional views of stacked device structure 10, in portion or entirety, along line B-B and line C-C, respectively, of FIG. 1A according to various aspects of the present disclosure. Stacked device structure 10 includes a device stack 12A and a device stack 12B. Device stack 12A and device stack 12B each include a respective device (e.g., an upper transistor) of an upper device 14U and a respective device (e.g., a lower transistor) of a lower device 14L. Device 14U and device 14L are disposed over a substrate 15, and an isolation structure 16 is disposed between device 14U and device 14L. Isolation structure 16 includes isolation structures 17 and isolation structures 18. In some embodiments, device 14U and device 14L are stacked back-to-front. For example, isolation structure 16 (e.g., isolation structures 17 thereof) may bond and/or attach a backside of device 14U to a frontside of device 14L. In such example, isolation structure 16 (and/or isolations structures 17 thereof) may be referred to as an isolation/bonding structure. Stacked device structure 10 may be fabricated monolithically and referred to as a monolithic stacked device structure. FIGS. 1A-1C have been simplified for the sake of clarity to better understand the inventive concepts of the present disclosure. Additional features may be added in stacked device structure 10, and some of the features described below may be replaced, modified, or eliminated in other embodiments of stacked device structure 10.

Referring to FIGS. 1A-IC, device 14U includes at least one electrically functional device, such as transistors 20U, and device 14L includes at least one electrically functional device, such as transistors 20L. Accordingly, device stack 12A is a transistor stack having a respective upper transistor 20U and a respective lower transistor 20, and device stack 12B is a transistor stack having a respective upper transistor 20U and a respective lower transistor 20. Transistors 20U may be separated and/or electrically isolated from respective transistors 20L by isolation structure 16. In the depicted embodiment, transistors 20U and transistors 20L are of an opposite conductivity type. For example, transistors 20U are n-type transistors, and transistors 20L are n-type transistors, or vice versa. In such embodiments, the transistor stacks (e.g., each having a respective transistor 20U and a respective transistor 20L) form CFETs. Device stack 12A and device stack 12B may thus be referred to as CFETs. In some embodiments, transistors 20U and transistors 20L are of a same conductivity type. For example, transistors 20U and transistors 20L are both configured as n-type transistors or both p-type transistors.

Device 14U includes various features and/or components, such as semiconductor layers 26U, semiconductor layers 26M, gate spacers 44, inner spacers 54, source/drains 62U, a contact etch stop layer (CESL) 70U, an interlayer dielectric (ILD) layer 72U, gate dielectrics 78U, gate electrodes 80U, and hard masks 92. A respective gate dielectric 78U and a respective gate electrode 80U collectively form an upper gate stack 90U. Device 14L includes various features and/or components, such as protrusions 15′ (which may be extensions of substrate 15), semiconductor layers 26L, semiconductor layers 26M, substrate isolation structures 28, fin spacers 46, inner spacers 54, source/drains 62L, a CESL 70L, an ILD layer 72L, gate dielectrics 78L, and gate electrodes 80L. A respective gate dielectric 78L and a respective gate electrode 80L collectively form a lower gate stack 90L. A respective gate stack 90U and a respective gate stack 90L are collectively referred to as a gate 90 (or gate stack) of a device stack (e.g., device stack 12A or device stack 12B), and gate 90 may provide a metal gate or a high-k/metal gate of a CFET. In some embodiments, gate stack 90U is separated from gate stack 90L by a respective isolation structure 17 (and semiconductor layers 26M, in the depicted embodiment), and source/drains 62L are separated from source/drains 62U by isolation structures 18.

Transistors 20L are configured as GAA transistors. For example, each of transistors 20L may include two channels (e.g., nanowires, nanosheets, nanobars, etc.) provided by semiconductor layers 26L (also referred to as channel layers or channels), which are suspended over substrate 15 and extend between respective source/drains (e.g., source/drains 62L). In some embodiments, transistors 20L may include more or less channels (and thus more or less semiconductor layers 26L). Each transistor 20L has a respective gate stack 90L disposed over its semiconductor layers 26L and between its source/drains 62L. Along a gate widthwise direction (FIG. 1A), the respective gate stack 90L may be over a respective top semiconductor layer 26L, between respective semiconductor layers 26L, and between a respective bottom semiconductor layer 26L and substrate 15 (e.g., protrusion 15′ thereof). Along a gate lengthwise direction (FIG. 1B), the respective gate stack 90L wraps around respective semiconductor layers 26L. During operation of the GAA transistors, current may flow through respective semiconductor layers 26L and between respective source/drains 62L. In the depicted embodiment, transistors 20L of adjacent device stacks, such as of device stack 12A and device stack 12B, have a common source/drain 62L, such as middle source/drain 62L depicted in FIG. 1A. In some embodiments, transistors 20L do not have a common source/drain 62L. Each of transistors 20L may further include semiconductor layers 26M (also referred to as dummy channel layers or dummy channels) suspended over substrate 15 and extending between respective isolation structures 18, and each device stack may include a respective isolation structure 17 disposed between semiconductor layer 26M of its respective transistor 20L and semiconductor layer 26M of its respective transistor 20U. Further, each of transistors 20L may include inner spacers 54 disposed between its gate stack (e.g., gate stack 90L) and its source/drains 62L.

Transistors 20U are also configured as GAA transistors. For example, each of transistors 20U may include two channels (e.g., nanowires, nanosheets, nanobars, etc.) provided by semiconductor layers 26U (also referred to as channel layers or channels), which are suspended over substrate 15 and extend between respective source/drains (e.g., source/drains 62U). In some embodiments, transistors 20U includes more or less channels (and thus more or less semiconductor layers 26U). Each transistor 20U has a respective gate stack 90U disposed over its semiconductor layers 26U and between its source/drains 62U. Along a gate widthwise direction (FIG. 1A), the respective gate stack 90U may be over a respective top semiconductor layer 26U, between respective semiconductor layers 26U, and between a respective bottom semiconductor layer 26U and a respective semiconductor layer 26M. Along a gate lengthwise direction (FIG. 1B), the respective gate stack 90U wraps around respective semiconductor layers 26U. During operation of the GAA transistors, current may flow through respective semiconductor layers 26U and between respective source/drains 62U. In the depicted embodiment, transistors 20U of adjacent device stacks, such as of device stack 12A and device stack 12B, have a common source/drain 62U, such as middle source/drain 62U depicted in FIG. 1A. In some embodiments, transistors 20U do not have a common source/drain 62U. Each of transistors 20U may further include semiconductor layers 26M (i.e., dummy channel layers) suspended over substrate 15 and extending between respective isolation structures 18. Further, transistors 20U may each include gate spacers 44 disposed along sidewalls of an upper portion of its gate stack (e.g., gate stack 90U), inner spacers 54 disposed between its gate stack and its source/drains 62U, and hard masks 92 disposed over its gate stack and between its gate spacers 44. Hard masks 92 may be considered a portion of the gate stacks.

Isolation structure 16 has isolation structures 17 and isolation structures 18 between channel regions and source/drain regions, respectively, of device 14L and device 14U. For example, isolation structures 17 are between channel regions of lower transistors (e.g., transistors 20L) and channel regions of upper transistors (e.g., transistors 20U) (e.g., between channels and/or gates thereof), and isolation structures 18 are between source/drain regions of lower transistors (e.g., transistors 20L) and source/drain regions of upper transistors (e.g., transistors 20U). In the depicted embodiment, isolation structures 17 are between semiconductor layers 26M of lower transistors and upper transistors, and isolation structures 18 are between source/drains 62L of lower transistors and source/drains 62U of upper transistors. Accordingly, isolation structures 17 may provide electrical isolation of channels and/or gates of stacked devices, and isolation structures 18 may provide electrical isolation of source/drains of stacked devices. Isolation structures 17 and isolation structures 18 may include a single layer or multiple layers. Isolation structures 17 and isolation structures 18 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, etc.). Isolation structures 17 and isolation structures 18 may include the same or different materials and/or configurations. In the depicted embodiment, a thickness of isolation structures 17 is less than a thickness of isolation structures 18, and a configuration of isolation structures 17 is different than a configuration of isolation structures 18. In some embodiments, isolation structures 18 include CESL 70L and ILD layer 72L, such as depicted (i.e., each isolation structure 18 is formed by a respective portion of CESL 70L and a respective portion of ILD layer 72L).

Substrate 15, semiconductor layers 26U, semiconductor layers 26M, and semiconductor layer 26L include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In the depicted embodiment, substrate 15 semiconductor layers 26U, semiconductor layers 26M, and semiconductor layers 26L include silicon. In some embodiments, semiconductor layers 26U and semiconductor layers 26L include different semiconductor materials, such as silicon and silicon germanium, respectively, or vice versa. In such embodiments, semiconductor layers 26M of transistors 20U and semiconductor layers 26M of transistors 20L may include different materials. In some embodiments, substrate 15 is a semiconductor-on-insulator substrate, such as a silicon-on-insulator (SOI) substrate, a silicon germanium-on-insulator (SGOI) substrate, or a germanium-on-insulator (GOI) substrate. Substrate 15 (including protrusions 14′ therefrom) may include various doped regions, such as p-wells and n-wells. The n-wells are doped with n-type dopants, such as phosphorus, arsenic, other n-type dopant, or combinations thereof. The p-wells are doped with p-type dopants, such as boron, indium, other p-type dopant, or combinations thereof. In some embodiments, semiconductor layers 26U, semiconductor layers 26M, and semiconductor layers 26L, or combinations thereof include p-type dopants, n-type dopants, or combinations thereof. For ease of description herein, semiconductor layers 26U, semiconductor layers 26M, and semiconductor layers 26L may be referred to collectively as semiconductor layers 26.

Substrate isolation structures 28 electrically isolate active device regions and/or passive device regions. For example, substrate isolation structures 28 separate and electrically isolate active regions of transistors 20L from one another and/or other device regions. Substrate isolation structures 28 includes silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 28 may have a multilayer structure. For example, substrate isolation structures 28 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 28 may include a bulk dielectric over a doped liner, such as a boron silicate glass (BSG) liner and/or a phosphosilicate glass (PSG) liner. Dimensions and/or characteristics of substrate isolation structures 28 are configured to provide shallow trench isolation (STI) structures, deep trench isolation (DTI) structures, local oxidation of silicon (LOCOS) structures, other suitable isolation structures, or combinations thereof.

Gate spacers 44 are disposed along sidewalls of top portions of gate stacks 90U, fin/protrusion spacers 46 are disposed along sidewalls of protrusions 15′, and inner spacers 54 are disposed under gate spacers 44 along sidewalls of gate stacks 90U and gate stacks 90L. Inner spacers 54 are between semiconductor layers 26U, between semiconductor layers 26L, between bottom semiconductor layers 26U and semiconductor layers 26M, between top semiconductor layers 26L and semiconductor layers 26M, and between bottom semiconductor layers 26M and mesas 15′. Gate spacers 44, fin spacers 46, and inner spacers 54 include a dielectric material. The dielectric material may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). Gate spacers 44, fin spacers 46, and inner spacers 54 may include different materials and/or different configurations (e.g., different numbers of layers). In some embodiments, gate spacers 44, fin spacers 46, inner spacers 54, or combinations thereof have a multilayer structure. In some embodiments, gate spacers 44 and/or fin spacers 46 include more than one set of spacers, such as seal spacers, offset spacers, sacrificial spacers, dummy spacers, main spacers, or combinations thereof. The various sets of spacers may have different compositions.

Each gate 90 may be disposed between respective source/drain stacks. A source/drain stack may include a respective source/drain 62U, a respective source/drain 62L, and a respective isolation structure 18 disposed therebetween. Source/drains 62L and source/drains 62U include semiconductor material, and source/drains 62L and source/drains 62U may be doped with n-type dopants and/or p-type dopants. In some embodiments, source/drains 62L and source/drains 62U are formed of epitaxially grown/deposited semiconductor material(s), and source/drains 62L and source/drains 62U are referred to as epitaxial source/drains. In some embodiments (e.g., when forming portions of n-type transistors), source/drains 62L and/or source/drains 62U include silicon doped with carbon, phosphorous, arsenic, other n-type dopant, or combinations thereof. In some embodiments (e.g., when forming portions of p-type transistors), source/drains 62L and/or source/drains 62U include silicon germanium or germanium doped with boron, other p-type dopant, or combinations thereof. Source/drains 62L and source/drains 62U may have the same or different compositions and/or materials depending on configurations of their respective transistors. For example, in some embodiments, where transistors 20U are n-type transistors and transistors 20L are p-type transistors, source/drains 62L may include silicon germanium doped with boron, and source/drains 62U may include silicon doped with phosphorous and/or carbon. In other embodiments, where transistors 20U are p-type transistors and transistors 20L are n-type transistors, source/drains 62U may include silicon germanium doped with boron, and source/drains 62L may include silicon doped with phosphorous and/or carbon. In some embodiments, doped regions, such as heavily doped source/drain (HDD) regions, lightly doped source/drain (LDD) regions, other doped regions, or combinations thereof, are disposed in source/drains 62L and/or source/drains 62U. In some embodiments, source/drains 62L and/or source/drains 62U include multiple semiconductor layers, and the semiconductor layers may include the same or different materials, compositions, dopant type, dopant concentrations, thicknesses, etc. In some embodiments, source/drains 62L and/or source/drains 62U include materials and/or dopants that achieve desired tensile stress and/or compressive stress in adjacent channel regions (e.g., formed by semiconductor layers 26U and semiconductor layers 26L). As used herein, source/drain region, source/drain, epitaxial source/drain, epitaxial source/drain feature, etc. may refer to a source of a device (e.g., a transistor), a drain of a device (e.g., a transistor), or a source and/or a drain of multiple devices.

ILD layer 72U and ILD layer 72L include a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 72U and/or ILD layer 72L include a dielectric material having a dielectric constant that is less than a dielectric constant of silicon dioxide (e.g., k<3.9). In some embodiments, ILD layer 72U and/or ILD layer 72L includes a dielectric material having a dielectric constant that is less than about 2.5 (i.e., an extreme low-k (ELK) dielectric material), such as porous silicon oxide, silicon carbide, carbon-doped oxide (e.g., an SiCOH-based material (having, for example, Si—CH₃ bonds)), or combinations thereof, each of which is tuned/configured to have a dielectric constant less than about 2.5. CESL 70L and CESL 70U include a dielectric material that is different than the dielectric material of ILD layer 72U and ILD layer 72L, respectively. For example, where ILD layer 72U and ILD layer 72L include a low-k dielectric material (e.g., porous silicon oxide), CESL 70L and CESL 70U may include silicon and nitrogen and/or carbon, such as silicon nitride, silicon carbonitride, or silicon oxycarbonitride. In some embodiments, CESL 70L and/or CESL 70U may include metal and oxygen, nitrogen, carbon, or combinations thereof. ILD layer 72U, ILD layer 72L, CESL 70L, CESL 70U, or combinations thereof may have a multilayer structure.

Gate dielectrics 78U and gate dielectrics 78L each include at least one dielectric gate layer. Gate dielectrics 78U and gate dielectrics 78L may have the same or different compositions, materials, layers, configurations, or combinations thereof. In some embodiments, gate dielectrics 78U and/or gate dielectrics 78L include an interfacial layer that includes a dielectric material, such as SiO₂, SiGeOₓ, HfSiO, SiON, other dielectric material, or combinations thereof. In some embodiments, gate dielectrics 78U and/or gate dielectrics 78L include a high-k dielectric layer, which includes a dielectric material having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or combinations thereof. For example, gate dielectrics 78U and/or gate dielectrics 78L may include a hafnium-based oxide (e.g., HfO₂) layer and/or a zirconium-based oxide (e.g., ZrO₂) layer. The interfacial layer and/or the high-k dielectric layer may have a multilayer structure.

Gate electrodes 80U and gate electrodes 80L are disposed over gate dielectrics 78U and gate dielectrics 78L, respectively. Gate electrodes 80U and gate electrodes 80L may have the same or different compositions, materials, layers, configurations, or combinations thereof. Gate electrodes 80U and gate electrodes 80L each include at least one electrically conductive gate layer formed of an electrically conductive material, such as Al, Cu, Ti, Ta, W, Mo, Co, TaN, NiSi, CoSi, TiN, WN, TiAl, TiAIN, TaCN, TaC, TaSiN, other electrically conductive material, or combinations thereof. In some embodiments, the electrically conductive gate layer includes a work function layer tuned to have a desired work function (e.g., an n-type work function or a p-type work function). The work function layer includes work function metal(s) and/or alloys thereof, such as Ti, Ta, Al, Ag, Mn, Zr, W, Ru, Mo, TIC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive gate layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive gate layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Hard masks 92 include a material that is different than ILD layer 72U and/or subsequently formed ILD layers to achieve etch selectivity during subsequent etching processes. In some embodiments, hard masks 92 include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, hard masks 92 include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HFO₂), zirconium aluminum oxide (e.g., ZrAlO), other metal oxide, other metal nitride, or combinations thereof.

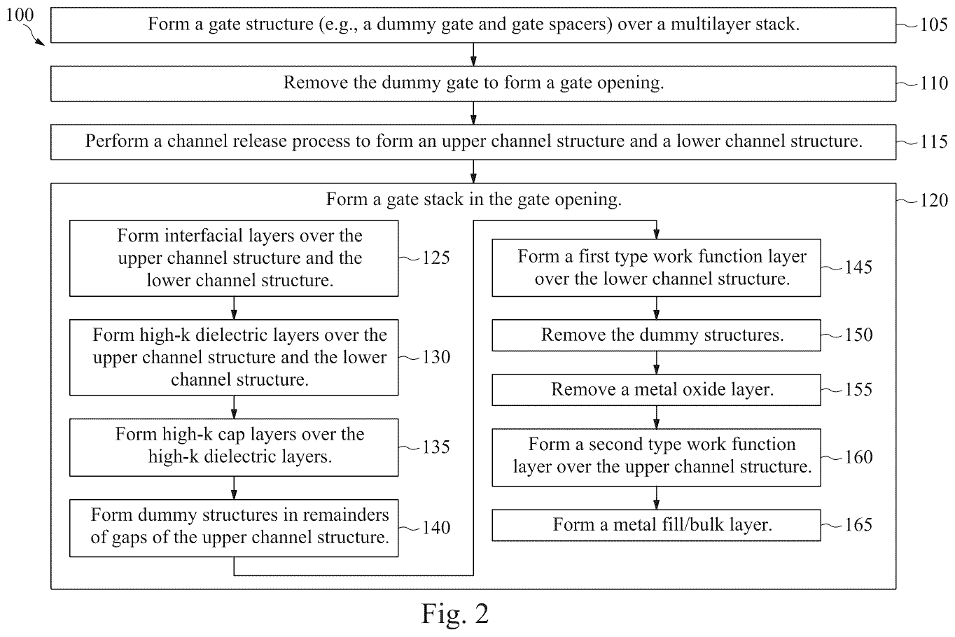

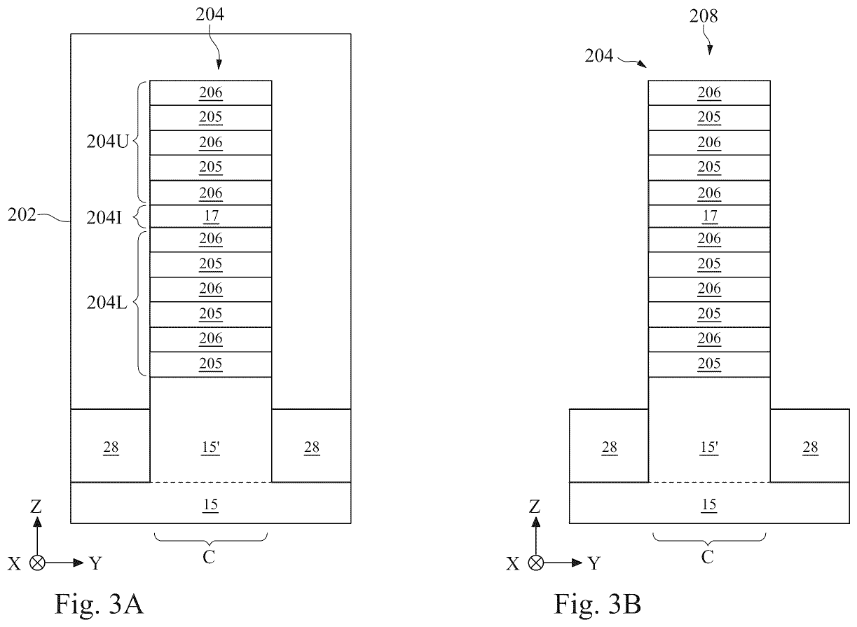

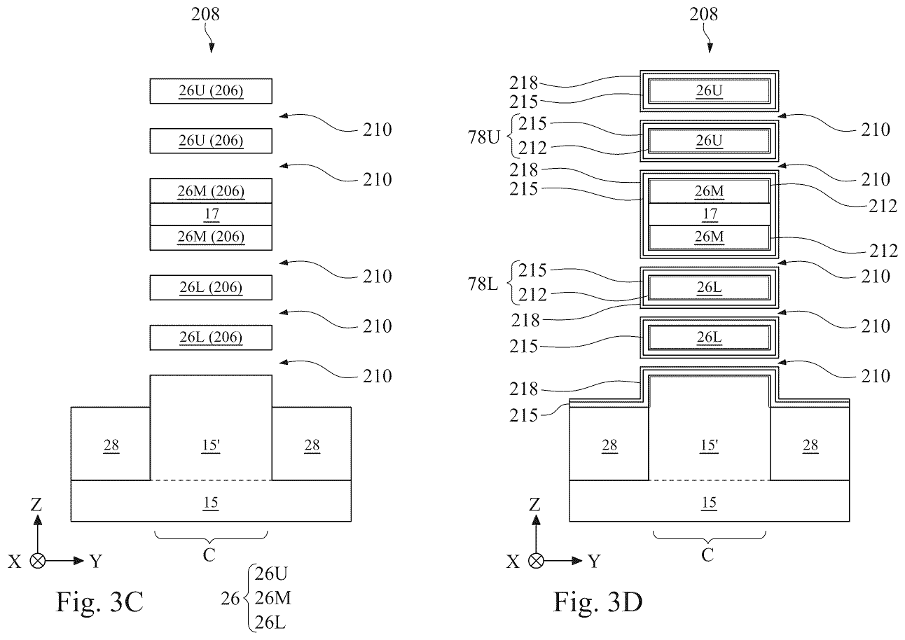

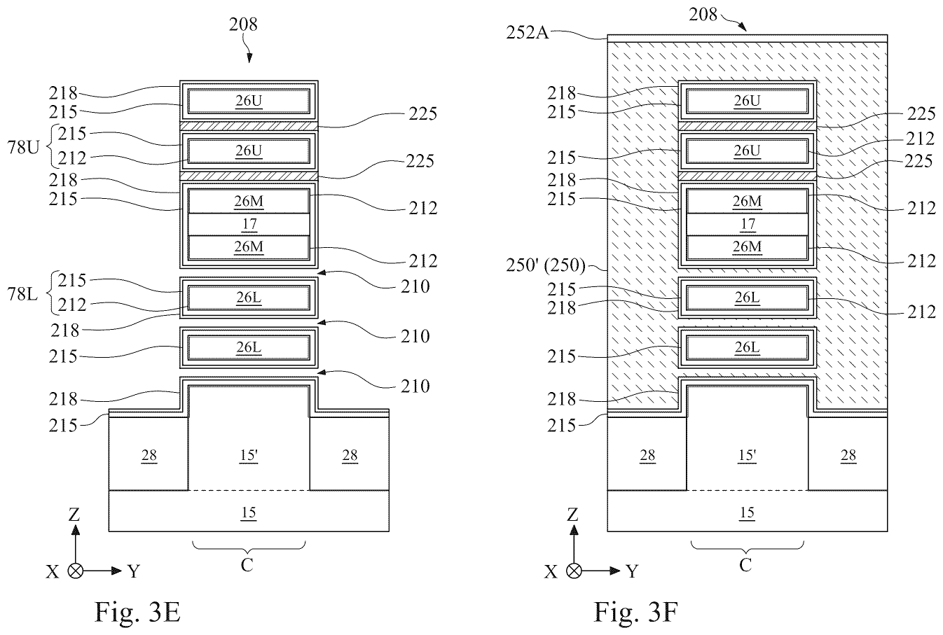

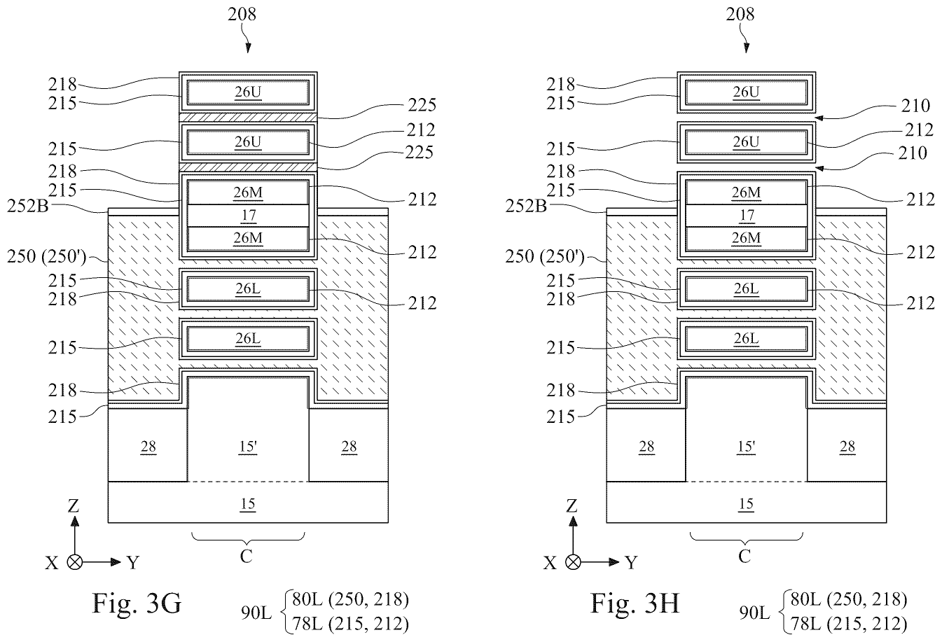

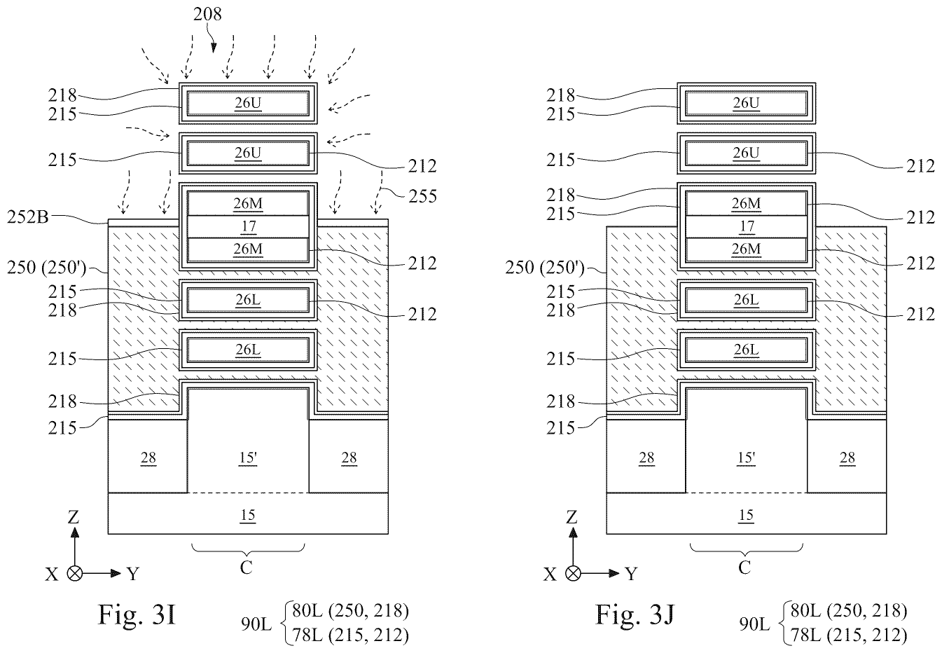

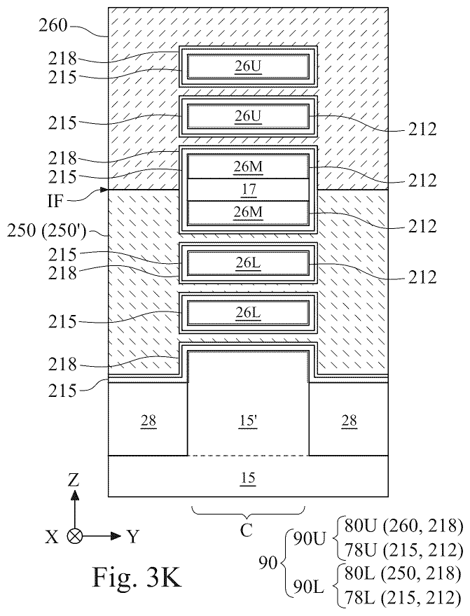

FIG. 2 is a flow chart of a method 100 for fabricating a gate stack of transistors of a transistor stack, such as gate 90 of a transistor stack of stacked device structure 10 of FIGS. 1A-1C, according to various aspects of the present disclosure. FIGS. 3A-3K are cross-sectional views of a stacked device structure, such as stacked device structure 10 of FIGS. 1A-1C, in portion or entirety, at various fabrication stages associated with method 100 of FIG. 2 according to various aspects of the present disclosure. Method 100 described with reference to FIGS. 3A-3K implements a native oxide removal process that eliminates and/or significantly reduces oxygen (e.g., metal oxide) at an interface of gate 90L and gate 90U, which may significantly reduce gate resistance and/or improve performance of stacked device structure 10. The cross-sectional views of FIGS. 3A-3K are taken (cut) along a gate lengthwise direction (e.g., a y-direction), like the cross-sectional view of FIG. 1B. FIG. 2 and FIGS. 3A-3K have been simplified for the sake of clarity to better understand the inventive concepts of the present disclosure. Additional steps can be provided before, during, and after method 100, and some of the steps described can be moved, replaced, or eliminated for additional embodiments of method 100. Additional features may be added in the stacked device structure of FIGS. 3A-3K, and some of the features described below can be replaced, modified, or eliminated in other embodiments of the stacked device structure of FIGS. 3A-3K.

Referring to FIG. 2 and FIG. 3A, method 100 may include forming a gate structure, which may include a dummy gate 202 and gate spacers 44 (e.g., in an X—Z cross-sectional view along a gate widthwise direction), over a multilayer stack 204 at block 105. The gate structure is disposed over multilayer stack 204 and between source/drain (S/D) regions (e.g., in the X—Z cross-sectional view). Dummy gate 202 extends along the y-direction, having a length along the y-direction, a width along the x-direction, and a height along the z-direction. Along the gate lengthwise direction (FIG. 3A), dummy gate 202 is disposed over a top and sidewalls of multilayer stack 204, and dummy gate 202 wraps multilayer stack 204. Along a gate widthwise direction (e.g., in the X—Z cross-sectional view), dummy gate 202 is disposed on a top of multilayer stack 204, and gate spacers 44 may be disposed adjacent to sidewalls of dummy gate 202. Dummy gate 202 may include a dummy gate electrode (e.g., a polysilicon layer) and a dummy gate dielectric (e.g., a silicon oxide layer). Dummy gate 202 may include additional layers, such as a hard mask layer. In some embodiments, a dielectric layer (e.g., CESL 70U and ILD layer 72U) is formed before or after forming the gate structure, and the gate structure is disposed in the dielectric layer. In some embodiments, source/drains (e.g., source/drains 62U and/or source/drains 62L) are formed before or after forming the gate structure, and the gate structure is disposed between source/drains (e.g., in the X—Z cross-sectional view).

Multilayer stack 204 includes an upper multilayer stack 204U, an intermediate stack 2041, a lower multilayer stack 204L, and protrusion 15′. Multilayer stack 204 extends lengthwise in a direction that is different than (e.g., orthogonal to) the lengthwise direction of dummy gate 202. For example, multilayer stack 204 extends along the x-direction, having a length along the x-direction, a width along the y-direction, and a height along the z-direction. Each of upper multilayer stack 204U and lower multilayer stack 204L include sacrificial layers 205 and semiconductor layers 206, and intermediate stack 2041 includes isolation structure 17. Multilayer stack 204 may be a portion of a device precursor that is formed and/or received before forming the gate structure. The device precursor may also include isolation structures 18 (e.g., in the X—Z cross-sectional view), substrate isolation structures 28, fin spacers 46 (e.g., in a Y—Z cross-sectional view of source/drain regions), inner spacers 54 (e.g., in the X—Z cross-sectional view), source/drains 62U (e.g., in the X—Z cross-sectional view), and source/drains 62L (e.g., in the X—Z cross-sectional view). Multilayer stack 204 is in a channel region C, and source/drains (e.g., source/drains 62U and source/drain 62L) are in source/drain regions S/D. Along the x-direction, each semiconductor layer 206 may extend between source/drains 62U, isolation structures 18, or source/drains 62L. Further, protrusion 15′ may extend between source/drains 62L, and inner spacers 54 may be between sacrificial layers 205 and source/drains 62U, 62L.

A composition of sacrificial layers 205 is different than a composition of semiconductor layers 206 to achieve etching selectivity and/or different oxidation rates during subsequent processing. For example, sacrificial layers 205 and semiconductor layers 206 include different materials, constituent atomic percentages, constituent weight percentages, other characteristics, or combinations thereof. In some embodiments, sacrificial layers 205 include silicon germanium, semiconductor layers 206 include silicon, and an etch rate of semiconductor layers 206 is different than an etch rate of sacrificial layers 205 to a given etchant. In some embodiments, sacrificial layers 205 and semiconductor layers 206 include the same material but with different constituent atomic percentages. For example, sacrificial layers 205 and semiconductor layers 206 include silicon germanium with different silicon atomic percentages and/or different germanium atomic percentages. In some embodiments, sacrificial layers 205 are dielectric layers (e.g., oxide layers) and semiconductor layers 206 are silicon layers or silicon germanium layers. In the depicted embodiment, semiconductor layers 206 of upper multilayer stack 204U and semiconductor layers 206 of lower multilayer stack 204L have a same composition (e.g., silicon). In some embodiments, semiconductor layers 206 of upper multilayer stack 204U and semiconductor layers 206 of lower multilayer stack 204L have different compositions (e.g., silicon and silicon germanium, respectively, or vice versa). Sacrificial layers 205 and semiconductor layers 206 may include any combination of materials that provides desired etching selectivity, desired oxidation rate differences, desired performance characteristics (e.g., materials that maximize current flow), or combinations thereof.

Referring to FIG. 2 and FIG. 3B, method 100 may include removing dummy gate 202 to form a gate opening 208 that exposes multilayer stack 204 at block 110. Gate opening 208 may have sidewalls formed by gate spacers 44 (e.g., in the X—Z cross-sectional view) and a bottom formed by multilayer stack 204 and/or substrate isolation structures 28. In some embodiments, an etching process selectively removes dummy gate 202 with respect to multilayer stack 204, substrate isolation structures 28, gate spacers 44, the dielectric layer, or combinations thereof. For example, the etching process removes dummy gate 202 without (or negligibly) removing protrusion 15′, sacrificial layers 205, semiconductor layers 206, isolation structure 17, gate spacers 44, substrate isolation structures 28, CESL 70U, ILD layer 72U, or combinations thereof. The etching process is a dry etch, a wet etch, other suitable etch, or combinations thereof. In some embodiments, a patterned mask layer exposes dummy gate 202 and covers CESL 70U, ILD layer 72U, gate spacers 44, or combinations thereof during the etching.

Turning to FIG. 2 and FIG. 3C, method 100 at block 115 includes performing a channel release process. The channel release process may include selectively removing sacrificial layers 205 exposed by gate opening 208 to form gaps 210 between semiconductor layers 206 and between bottom semiconductor layer 206 and protrusion 15′, thereby suspending semiconductor layers 206 in channel region C. In the depicted embodiment, six semiconductor layers 206 are vertically stacked along the z-direction and suspended over protrusion 15′ after the channel release process. Top semiconductor layers 206 (of upper multilayer stack 204U) may provide channels through which current may flow between source/drains 62U, and thus, may be referred to as semiconductor layers 26U, channels 26U, an upper channel structure, or combinations thereof. Bottom semiconductor layers 206 (of lower multilayer stack 204L) may provide channels through which current may flow between source/drains 62L, and thus, may be referred to as semiconductor layers 26L, channels 26L, a lower channel structure, or combinations thereof. Middle semiconductor layers 206 (one of upper multilayer stack 204U and one of lower multilayer stack 204L) extend between isolation structures 18 and may not function as channels, and thus, may be referred to as semiconductor layers 26M and/or dummy channels 26M. Semiconductor layers 26M and isolation structure 17 combine to form an intermediate structure between the upper channel structure and the lower channel structure. In some embodiments, the intermediate structure includes only isolation structure 17. For case of description and understanding, semiconductor layer 26U, semiconductor layer 26L, and semiconductor layers 26M may collectively be referred to as semiconductor layers 26. Further, the upper channel structure and lower channel structure having the intermediate structure therebetween may be referred to as a channel stack of stacked device structure 10.

In some embodiments, the channel release process includes an etching process that selectively etches sacrificial layers 205 without (or negligibly) etching semiconductor layers 206, protrusion 15′, isolation structure 17, gate spacers 44, inner spacers 54, substrate isolation structures 28, the dielectric layer, or combinations thereof. An etchant may be selected for the etching process that etches silicon germanium (i.e., sacrificial layers 205) at a higher rate than silicon (i.e., semiconductor layers 206 and protrusion 15′) and dielectric materials (i.e., the etchant has a high etch selectivity with respect to silicon germanium). The etching process is a dry etch, a wet etch, other suitable etching process, or combinations thereof. In some embodiments, before the etching process, an oxidation process may convert sacrificial layers 205 into semiconductor oxide features (e.g., silicon germanium oxide), and the etching process then removes the semiconductor oxide features. In some embodiments, during and/or after removing sacrificial layers 205, an etching process is performed to modify a profile of semiconductor layers 206 to provide target dimensions and/or target shapes thereof. For example, the etching process may provide semiconductor layers 206 with cylindrical-shaped profiles (e.g., nanowires), rectangular-shaped profiles (e.g., nanobars), sheet-shaped profiles (e.g., nanosheets), or any other suitable shaped profile. In some embodiments, semiconductor layers 206 have nanometer-sized dimensions and may be referred to as “nanostructures.” In some embodiments, semiconductor layers 206 have sub-nanometer dimensions and/or other suitable dimensions.

Referring to FIG. 2 and FIG. 3D, method 100 at block 125 includes forming interfacial layers 212 over the upper channel structure (e.g., semiconductor layer 26U) and the lower channel structure (e.g., semiconductor layers 26M). Interfacial layers 212 partially fill gate opening 208 and gaps 210. Interfacial layers 212 are formed by thermal oxidation, chemical oxidation, atomic layer deposition (ALD), chemical vapor deposition (CVD), other suitable process, or combinations thereof. In the depicted embodiment, interfacial layers 212 form on semiconductor surfaces (e.g., semiconductor layers 206), but not dielectric surfaces (e.g., substrate isolation structures 28 and/or isolation structures 17). Accordingly, respective interfacial layers 212 surround semiconductor layers 26U, respective interfacial layers 212 surround semiconductor layers 26L, a respective interfacial layer 212 wraps protrusion 15′, and respective interfacial layers 212 wrap semiconductor layers 26M. In the X—Z cross-sectional view (e.g., FIG. 1A), interfacial layers 212 may cover tops and bottoms of semiconductor layers 26U, tops and bottoms of semiconductor layers 26L, top of upper semiconductor layer 26M, bottom of lower semiconductor layer 26M, and top of protrusion 15′. Interfacial layers 212 include a dielectric material, such as SiO₂, SiGeOₓ, HfSiO, SiON, other dielectric material, or combinations thereof. In some embodiments, interfacial layers 212 are group IV-based oxide layers, which generally refer to oxides of a group IV-based material (i.e., a material that includes at least one group IV element, such as Si, Ge, C, etc.). In some embodiments, interfacial layers 212 are group III-V-based oxide layers, which generally refer to oxides of a group III-V-based material (i.e., a material that includes at least one group III element, such as Al, Ga, In, B, etc., and at least one group V element, such as N, P, As, Sb, etc.). In some embodiments, interfacial layers 212 have a substantially uniform thickness, such as depicted. In some embodiments, a thickness of interfacial layers is about 0.5 nm to about 2 nm.

Referring to FIG. 2 and FIG. 3D, method 100 at block 130 includes forming high-k dielectric layers 215 over the upper channel structure (e.g., semiconductor layers 26U) and the lower channel structure (e.g., semiconductor layers 26M). High-k gate dielectric layers 215 are formed over interfacial layers 212, partially fill gate opening 208, and partially fill gaps 210. High-k dielectric layers 215 are formed by ALD, CVD, physical vapor deposition (PVD), an oxide-based deposition process, other suitable process, or combinations thereof. In some embodiments, a dipole engineering process is performed after depositing high-k dielectric layers 215, and the dipole engineering process may incorporate dipole dopants into high-k dielectric layers 215 and/or interfacial layers 212 (which may adjust threshold voltages of transistors corresponding therewith). In the depicted embodiment, respective high-k dielectric layers 215 surround semiconductor layers 26U, respective high-k dielectric layers 215 surround semiconductor layers 26L, and a respective high-k dielectric layer 215 wraps protrusion 15′ and extends over tops of substrate isolation structures 28. Further, a respective high-k dielectric layer 215 surrounds the intermediate structure of the channel stack, such that the respective high-k dielectric layer 215 wraps upper semiconductor layer 26M, wraps lower semiconductor layer 26M, and extends along sidewalls of isolation structure 17. In the X—Z cross-sectional view (e.g., FIG. 1A), high-k dielectric layers 215 may cover tops and bottoms of semiconductor layer 26U, tops and bottoms of semiconductor layers 26L, top of upper semiconductor layer 26M, bottom of lower semiconductor layer 26M, and top of protrusion 15′. In the X—Z cross-sectional view (e.g., FIG. 1A), top portions of high-k dielectric layers 215 may have u-shaped profiles.

High-k dielectric layers 215 include a high-k dielectric material, which generally refers to dielectric materials having a dielectric constant that is greater than a dielectric constant of silicon dioxide (k˜3.9), such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃P₄, HfO₂—Al₂O₃, other high-k dielectric material, or combinations thereof. In some embodiments, high-k dielectric layers 215 are hafnium-based oxide (e.g., HfOₓ, such as HfO₂) layers. In some embodiments, high-k dielectric layers 215 are aluminum-based oxide (e.g., AlOₓ, such as Al₂O₃) layers. In some embodiments, high-k dielectric layers 215 are lanthanum-based oxide (e.g., LaOₓ, such as La₂O₃) layers. In some embodiments, high-k dielectric layers 215 are zirconium-based oxide (e.g., ZrOₓ, such as ZrO₂) layers. In some embodiments, high-k dielectric layers 215 are zinc-based oxide (e.g., ZnOₓ) layers. In some embodiments, high-k dielectric layers 215 have multilayer structures. In some embodiments, high-k dielectric layers 215 have a substantially uniform thickness, such as depicted. In the depicted embodiment, a thickness of high-k dielectric layers 215 is greater than a thickness of interfacial layers 212.

Processing associated with FIG. 3D provides gate dielectrics 78U and gate dielectrics 78L of stacked device structure 10. For example, interfacial layers 212 and high-k dielectric layers 215 around semiconductor layers 26U may provide a respective gate dielectric 78U of a respective transistor 20U, and interfacial layers 212 and high-k dielectric layers 215 around semiconductor layers 26L may provide a respective gate dielectric 78L of a respective transistor 20L. Interfacial layers 212 of gate dielectric 78U may have the same or different compositions, materials, layers, configurations, etc. of interfacial layers 212 of gate dielectric 78L. High-k dielectric layers 215 of gate dielectric 78U may have the same or different compositions, materials, layers, configurations, etc. of high-k dielectric layers 215 of gate dielectric 78L. In some embodiments, transistors of stacked device structure 10 are provided with different gate dielectrics (i.e., gate dielectric 78U and gate dielectric 78L have different compositions), which may adjust their threshold voltages. In some embodiments, the transistors have high-k dielectric layers 215 having different compositions. For example, high-k dielectric layers 215 of gate dielectric 78L may include a high-k dielectric metal (e.g., hafnium and/or zirconium), oxygen, and a dipole metal, while high-k dielectric layers 215 of gate dielectric 78U may include the high-k dielectric metal and oxygen (i.e., high-k dielectric layers 215 of gate dielectric 78U do not include the dipole metal). In another example, high-k dielectric layers 215 of gate dielectric 78U may include the high-k dielectric metal, oxygen, and a dipole metal that is different than the dipole metal of high-k dielectric layers 215 of gate dielectric 78L. For example, high-k dielectric layers 215 of gate dielectric 78U may include an n-dipole metal (e.g., lanthanum, yttrium, lutetium, strontium, erbium, magnesium, other suitable n-dipole dopant, or combinations thereof), and high-k dielectric layers 215 of gate dielectric 78L may include a p-dipole metal (aluminum, titanium, zinc, other suitable p-dipole dopant, or combinations thereof), or vice versa. In some embodiments, the transistors have interfacial layers 212 having different compositions. For example, interfacial layers 212 of gate dielectric 78L may include silicon, oxygen, and the dipole metal, while interfacial layers 212 of gate dielectric 78U may include silicon and oxygen, but either no dipole metal or a different dipole metal.

Referring to FIG. 2 and FIG. 3D, method 100 at block 135 may include forming high-k cap layers 218 over high-k dielectric layers 215. High-k cap layers 218 partially fill gate opening 208 and partially fill gaps 210. In the depicted embodiment, respective high-k cap layers 218 surround semiconductor layers 26U, respective high-k cap layers 218 surround semiconductor layers 26L, and a respective high-k cap layer 218 wraps protrusion 15′ and extends over tops of substrate isolation structures 28. Further, a respective high-k cap layer 218 surrounds the intermediate structure of the channel stack, such that the respective high-k cap layer 218 wraps upper semiconductor layer 26M, wraps lower semiconductor layer 26M, and extends along sidewalls of isolation structure 17. In the X—Z cross-sectional view (e.g., FIG. 1A), high-k cap layers 218 may be disposed over tops and bottoms of semiconductor layer 26U, tops and bottoms of semiconductor layers 26L, top of upper semiconductor layer 26M, bottom of lower semiconductor layer 26M, and top of protrusion 15′. In the X—Z cross-sectional view (e.g., FIG. 1A), top portions of high-k cap layers 218 may have u-shaped profiles.

High-k cap layers 218 include a material that prevents or eliminates diffusion and/or reaction of constituents between high-k dielectric layers 215 and other layers of gates 90 (e.g., gate electrodes thereof, such as gate electrodes 80U and/or gate electrodes 80L). In some embodiments, high-k cap layers 218 includes a metal and nitrogen, such as titanium nitride (TiN), tantalum nitride (TaN), tungsten nitride (W₂N), titanium silicon nitride (TiSiN), tantalum silicon nitride (TaSiN), or combinations thereof. For example, high-k cap layers 218 may be titanium silicon nitride layers. In some embodiments, high-k cap layers 218 have multilayer structures. For example, each of −k cap layers 218 may include a silicon cap disposed over a metal nitride cap (e.g., a titanium nitride layer). High-k cap layers 218 are formed by ALD, CVD, other suitable process, or combinations thereof. In some embodiments, high-k cap layers 218 have a substantially uniform thickness, such as depicted.

Referring to FIG. 2 and FIG. 3E, method 100 at block 140 may include forming dummy (sacrificial) structures 225 in remainders of gaps 210 of the upper channel structure. For example, dummy structures 225 are formed in remainders of gaps 210 between semiconductor layers 26U and between semiconductor layer 26U and semiconductor layer 26M (i.e., gaps 210 above isolation structure 17, which correspond with transistor 20U and/or device 14U). Dummy structures 225 include a material that is different than a material of high-k cap layers 218 to achieve etching selectivity therebetween, such that dummy structures 225 may be selectively etched without (or negligibly) etching high-k cap layers 218. The material of dummy structures 225 is also different than a gate electrode material of transistor 20L (e.g., a p-type work function material of a p-type work function layer, which may subsequently be formed as, or as a portion of, gate electrode 80L) to achieve etching selectivity therebetween, such that dummy structures 225 may be selectively etched without (or negligibly) etching the gate electrode material (e.g., p-type work function layer), and vice versa. The material of dummy structures 225 may also be different than dielectric materials of ILD layer 72U and/or CESL 70U to achieve etching selectivity therebetween, such that dummy structures 225 may be selectively etched without (or negligibly) etching ILD layer 72U and/or CESL 70U. In the depicted embodiment, dummy structures 225 are oxide structures, nitride structures, carbide structures, or combinations thereof. For example, dummy structures 225 may include silicon, oxygen, nitrogen, carbon, other suitable dielectric constituent, or combinations thereof (e.g., silicon oxide, silicon nitride, silicon carbide, or combinations thereof). In another example, dummy structures 225 include metal (e.g., aluminum) and oxygen and/or nitrogen (and may thus be referred to as metal oxide structures and/or metal nitride structures). In yet another example, dummy structures 225 may be formed of polysilicon. In yet another example, dummy structures 225 may be formed of semiconductor material, such as silicon. The present disclosure contemplates dummy structures 225 including any materials that can provide the desired etching selectivity as described herein.

Referring to FIG. 2, FIG. 3F, and FIG. 3G, method 100 at block 145 includes forming a first type work function layer, such as a p-type work function metal (PWFM) layer 250 (also referred to as a p-metal layer), over the lower channel structure (e.g., semiconductor layers 26L). PWFM layer 250 partially fills gate opening 208 and remainders of gaps 210 of the lower channel structure. For example, PWFM layer 250 fills remainders of gaps 210 between semiconductor layers 26L, between semiconductor layer 26L and semiconductor layer 26M, and between semiconductor layer 26L and protrusion 15′ (i.e., gaps 210 below isolation structure 17, which correspond with transistor 20L and/or device 14L). PWFM layer 250 surrounds the lower channel structure (e.g., semiconductor layers 26L thereof), and PWFM layer 250 may wrap lower semiconductor layer 26M of the intermediate structure, extend along sidewalls of isolation structure 17 of the intermediate structure, and wrap a top portion of protrusion 15′. Along the gate widthwise direction (e.g., in the X—Z cross-sectional view (e.g., FIG. 1A)), PWFM layer 250 may be over tops and bottoms of semiconductor layers 26L, bottoms of lower semiconductor layers 26M, and tops of protrusions 15′; and portions of PWFM layer 250 may be surrounded by respective high-k dielectric layers 215 and/or high-k cap layers 218. In some embodiments, gate electrode 80L of transistor 20L includes both PWFM layer 250 and respective high-k cap layers 218 (e.g., those disposed over the lower channel structure). In some embodiments, gate electrode 80L includes PWFM layer 250 alone. Dummy structures 225 may prevent PWFM layer 250 from forming between semiconductor layers 26 of the upper channel structure, such as between semiconductor layers 26U and/or between semiconductor layer 26U and upper semiconductor layer 26M (e.g., that disposed above isolation structure 17).

PWFM layer 250 includes a p-type work function metal material, which generally refers to an electrically conductive material having a p-type work function. In some embodiments, PWFM layer 250 and/or the p-type work function metal material has a work function greater than about 4.8 electron volts (eV), such as about 4.8 eV to about 5.5 eV. The p-type work function metal material includes titanium, tantalum, ruthenium, molybdenum, tungsten, palladium, platinum, iridium, other p-metal, alloys thereof, or combinations thereof. For example, PWFM layer 250 may be a titanium nitride layer, a molybdenum nitride layer, a palladium layer, a platinum layer, an iridium layer, a ruthenium layer, or combinations thereof. In the depicted embodiment, PWFM layer is a titanium nitride layer. In some embodiments, PWFM layer 250 has a multilayer structure (e.g., more than one PWFM layer).

Referring to FIG. 3F, forming PWFM layer 250 may include depositing a PWFM material 250′ over the channel stack by ALD, CVD, PVD, plating, other suitable process, or combinations thereof. A height of PWFM material 250′ is greater than a height of the channel stack, such that, in the depicted embodiment, PWFM material 250′ wraps the channel stack. Further, PWFM material 250′ fills gaps 210. In some embodiments, where PWFM layer 250 includes more than one PWFM layer, forming PWFM material 250′ may include multiple deposition steps. For example, PWFM layer 250 may include three PWFM sublayers, and forming PWFM material 250′ may include a first deposition to form a first PWFM sublayer over high-k cap layers 218, a second deposition to form a second PWFM sublayer over the first PWFM sublayer, and a third deposition to form a third PWFM sublayer over the second PWFM sublayer. In such example, PWFM material 250′/PWFM layer 250 includes the first PWFM sublayer, the second PWFM sublayer, and the third PWFM sublayer. In some embodiments, a thickness of PWFM layer 250 and/or each PWFM sublayer is about 0.5 nm to about 5 nm.

Referring to FIG. 3G, forming PWFM layer 250 may further include recessing PWFM material 250′ below the upper channel structure (e.g., semiconductor layers 26U), such that PWFM material 250′ is removed from over the upper channel structure. The recessing reduces a height of PWFM material 250′, such that a top of PWFM layer 250 is below the upper channel structure. PWFM material 250′ is recessed to at least the intermediate structure, but no further than intermediate structure. For example, PWFM material 250′ may be recessed below the portion of the intermediate structure that is above isolation structure 17 (e.g., upper semiconductor layer 26M) and/or below a top of isolation structure 17, such as depicted. In some embodiments, an etching process selectively removes PWFM material 250′ with respect to high-k cap layers 218 (e.g., those over the upper channel structure) and dummy structures 225. For example, the etching process etches PWFM material 250′ without (or negligibly) etching high-k cap layers 218 and dummy structures 225. The etching process is a dry etch, a wet etch, other suitable etch, or combinations thereof. In some embodiments, an etchant of the etching process may etch PWFM material 250′ at a higher rate than high-k cap layers 218 (or high-k dielectric layers 215, such as in embodiments where high-k cap layers 218 are omitted).

Referring to FIG. 2 and FIG. 3H, method 100 at block 150 may include removing dummy structures 225. For example, since dummy structures 225 function to protect upper gate region of stacked device structure 10 during formation of PWFM layer 250 (e.g., by preventing formation of PWFM layer 250 in gaps 210 between semiconductor layers 26U, which may be difficult to remove and undesirably alter characteristics of transistor 20U, such as a threshold voltage thereof), dummy structures 225 may be removed after forming PWFM layer 250. In some embodiments, an etching process selectively removes dummy structures 225 with respect to high-k cap layers 218 (or high-k dielectric layers 215, such as in embodiments where high-k cap layers 218 are omitted) and PWFM layer 250. For example, the etching process etches dummy structures 225 without (or negligibly) etching high-k cap layers 218 (or high-k dielectric layers 215) and PWFM layer 250. The etching process is a dry etch, a wet etch, other suitable etch, or combinations thereof. In some embodiments, an etchant of the etching process may etch dummy structures 225 at a higher rate than high-k cap layers 218 (or high-k dielectric layers 215) and PWFM layer 250. In some embodiments, a wet etch uses an NH₄OH-based wet etching solution to remove dummy structures 225. Parameters of the etching process may be controlled to ensure complete removal of dummy structures 225, such as etching temperature, etching solution concentration, etching time, other suitable wet etch parameters, or combinations thereof. In some embodiments, a wet etch uses a wet etchant that includes H₂O, NH₄OH, HCl, H₂O₂, other suitable wet etch chemicals, or combinations thereof. In some embodiments, the wet etchant may be a mixture of NH₄OH, H₂O₂, and H₂O (e.g., DIW).

The present disclosure recognizes that, sometimes, a metal oxide layer undesirably forms over PWFM layer 250 and/or PWFM material 250′. For example, oxygen in an ambient (e.g., air) around stacked device structure 10 during fabrication may react with metal at exposed surfaces of PWFM material 250′ (e.g., a top surface thereof) and/or exposed surfaces of PWFM layer 250 (e.g., a top surface thereof), thereby forming a metal oxide layer 252A and a metal oxide layer 252B, respectively. For example, where PWFM material 250′ is titanium nitride and PWFM layer 250 is a titanium nitride layer, oxygen in the ambient may react with titanium, and metal oxide layer 252A and metal oxide layer 252B may be titanium oxide layers (e.g., TiO₂ layers). Though metal oxide layer 252A is removed by recessing (e.g., etching back) PWFM material 250′ to form PWFM layer 250, metal oxide layer 252B undesirably remains over PWFM layer 250 and between PWFM layer 250 and a subsequently formed gate layer (e.g., a second type work function layer). The present disclosure recognizes that native oxide, such as metal oxide layer 252B, between gate stack 90U and gate stack 90L (e.g., between work function layers thereof) causes and/or increases gate resistance, which may undesirably change characteristics of and/or degrade performance of stacked device structure 10.

Accordingly, referring to FIG. 2, FIG. 3I, and FIG. 3J, method 100 at block 155 includes removing metal oxide layer 252B and/or any metal oxide (and/or other native oxide) from PWFM layer 250, such that a top surface of PWFM layer 250 (over which another metal gate layer is formed) is substantially free of oxygen. In some embodiments, a chlorine-based gas treatment 255 is performed to remove metal oxide layer 252B. Chlorine-based gas treatment 255 includes exposing metal oxide layer 252B to a chlorine-containing gas, which reacts with and/or breaks down metal oxide layer 252B until completely removed from PWFM layer 250. The chlorine-containing gas includes a transition metal and chlorine (i.e., a transition metal chloride), such as TaCl₅, TiCl₄, WCI₅, other transition metal chloride, or combinations thereof. In some embodiments, such as where PWFM layer 250 is a titanium nitride layer and metal oxide layer 252B is a titanium oxide layer, gaseous (g) transition metal chloride (e.g., X—Cl, where X is a transition metal) may react with the titanium oxide layer (e.g., TiO₂ in solid(s) form) to provide gaseous transition metal oxychloride (e.g., XOCl) and gaseous titanium oxychloride (e.g., TiOClₓ), such as illustrated by the following reaction:

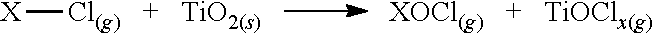

Parameters of the chlorine-based gas treatment 255 may be controlled to ensure complete removal of metal oxide layer 252B without (or negligibly) modifying PWFM layer 250 and high-k cap layers 218 (or high-k dielectric layers 215, such as in embodiments where high-k cap layers 218 are omitted), such as treatment temperature, a flow rate of the transition metal chloride, a flow rate of a carrier gas (e.g., an inert gas, such as helium, argon, nitrogen, xenon, other inert gas, or combinations thereof), treatment time, treatment pressure, other chlorine-based gas treatment parameters, or combinations thereof. In some embodiments, metal oxide layer 252B is removed by exposure to the chlorine-containing gas (e.g., gaseous transition metal chloride) without using a plasma. In some embodiments, chlorine-based gas treatment 255 may generate transition-metal-and-chlorine-containing plasma from the chlorine-containing gas (e.g., gaseous transition metal chloride), which removes metal oxide layer 252B.

Referring to FIG. 2 and FIG. 3K, method 100 at block 160 includes forming a second type work function layer, such as an n-type work function metal (NWFM) layer 260 (also referred to as an n-metal layer), over the upper channel structure (e.g., semiconductor layers 26U). NWFM layer 260 partially fills gate opening 208 and remainders of gaps 210 of the upper channel structure. For example, NWFM layer 260 fills remainders of gaps 210 between semiconductor layers 26U and between semiconductor layer 26U and semiconductor layer 26M (i.e., gaps 210 above isolation structure 17, which correspond with transistor 20U and/or device 14U). NWFM layer 260 surrounds the upper channel structure (e.g., semiconductor layers 26U thereof), NWFM layer 260 may wrap upper semiconductor layer 26M of the intermediate structure, and NWFM layer 260 may extend along sidewalls of isolation structure 17 of the intermediate structure. Along the gate widthwise direction (e.g., in the X-Z cross-sectional view (e.g., FIG. 1A)), NWFM layer 260 may be disposed over tops and bottoms of semiconductor layers 26U and tops of upper semiconductor layers 26M; portions of NWFM layer 260 may be surrounded by respective high-k dielectric layers 215 and/or high-k cap layers 218; and portions of NWFM layer 260 above topmost semiconductor layers 26U may be wrapped by high-k dielectric layers 215 and/or high-k cap layers 218, such as those having u-shaped profiles. In some embodiments, gate electrode 80U of transistor 20U includes both NWFM layer 260 and respective high-k cap layers 218 (e.g., those disposed over the upper channel structure). In some embodiments, gate electrode 80U includes NWFM layer 260 alone.

NWFM layer 260 includes an n-type work function metal material, which generally refers to an electrically conductive material having an n-type work function. In some embodiments, NWFM layer 260 and/or the n-type work function metal material has a work function less than about 4.5 eV, such as about 3.5 eV to about 4.5 eV. The n-type work function metal material may include aluminum, titanium, tantalum, zirconium, other n-metal, alloys thereof, or combinations thereof. For example, NWFM layer 260 may be a titanium aluminum layer, a titanium aluminum carbide layer, a tantalum layer, a tantalum aluminum layer, a tantalum aluminum carbide layer, or combinations thereof. In the depicted embodiment, NWFM layer is a titanium aluminum layer or a titanium aluminum carbide layer. In some embodiments, NWFM layer 260 has a multilayer structure (e.g., more than one NWFM layer).

Forming NWFM layer 260 may include depositing an n-type work function material over PWFM layer 250 and the upper channel stack (e.g., semiconductor layers 26U) by ALD, CVD, PVD, plating, other suitable process, or combinations thereof. A thickness of NWFM layer 260 is greater than a height of the channel stack, such that, in the depicted embodiment, NWFM layer 260 is disposed over a top of and wraps the channel stack. Further, NWFM layer 260 fills gaps 210. In some embodiments, where NWFM layer 260 includes more than one NWFM layer, forming the NWFM material may include multiple deposition steps. For example, NWFM layer 260 may include NWFM sublayers, and forming the NWFM material may include a respective deposition step to form each of the NWFM sublayers. In some embodiments, a thickness of NWFM layer 260 and/or each NWFM sublayer is about 0.5 nm to about 5 nm. In some embodiments, forming NWFM layer 260 may include performing a planarization process (e.g., CMP) to remove excess NWFM material, such as that disposed over ILD layer 72U and/or CESL 70U. In furtherance of such example, remaining portions of the NWFM material provide NWFM layer 260. In some embodiments, forming NWFM layer 260 includes recessing (e.g., etching back) the NWFM material. In such embodiments, the recessing includes an etching process that may selectively remove the NWFM material with respect to ILD layer 72U and/or CESL 70U. For example, the etching process etches the NWFM material without (or negligibly) etching ILD layer 72U and/or CESL 70U (and, in some embodiments, gate spacers 44). The etching process is a dry etch, a wet etch, other suitable etch, or combinations thereof.

To reduce/prevent exposure of PWFM layer 250 to oxygen ambient after removal of native oxide (e.g., metal oxide layer 252B) and thus reduce/prevent additional formation of native oxide, removal of metal oxide layer 252A and deposition of NWFM layer 260 are performed in-situ. For example, stacked device structure 10 remains under vacuum conditions during chlorine-based gas treatment 255 (i.e., native/metal oxide removal), deposition of NWFM layer 260, and therebetween. As used herein, the term “in-situ” is used to describe processes that are performed while a device or a substrate remains within a processing system (e.g., within a CVD tool and/or reactor) and/or a process chamber, and where for example, the processing system and/or the process chamber allows the device to remain under vacuum conditions. As such, the term “in-situ” may also generally refer to processes in which the device or substrate being processed is not exposed to an external ambient (e.g., external to the processing system, such as air), such as in between the processes. In some embodiments, chlorine-based gas treatment 255 and deposition of NWFM layer 260 (e.g., by CVD) are performed within a same process chamber (e.g., a CVD process chamber) and/or a same process tool (e.g., a CVD tool), such that stacked device structure 10 may remain under vacuum conditions.

In some embodiments, NWFM layer 260 fills a remainder of gate opening 208. In some embodiments, NWFM layer 260 partially fills gate opening 208, and another electrically conductive gate layer is formed over NWFM layer 260 and/or PWFM layer 250. For example, method 100 may include forming a metal fill/bulk layer in gate opening 208 at block 165. The metal fill/bulk layer may fill the remainder of gate opening 208, and the metal fill/bulk layer may be disposed over NWFM layer 260 and PWFM layer 250. In such embodiments, gate electrode 80U and/or gate electrode 80L may further include the metal fill/bulk layer. The metal fill/bulk layer includes aluminum, tungsten, cobalt, copper, other suitable electrically conductive material, alloys thereof, or combinations thereof. In such example, gate stack fabrication may include depositing a metal fill/bulk material over the n-type work function material after deposition thereof and performing a planarization process (e.g., CMP) to remove excess metal fill/bulk material and/or work function material (e.g., n-type and/or p-type), such as that disposed over ILD layer 72U and/or CESL 70U. In furtherance of such example, remaining portions of the metal-fill bulk material provide the metal/fill bulk layer, and remaining portions of the work function material provide NWFM layer 260 and/or PWFM layer 250. In some embodiments, a barrier layer may be formed between the metal fill/bulk layer and NWFM layer 260 and/or between the metal fill/bulk layer and PWFM layer 250. In some embodiments, a work function barrier layer may be formed between NWFM layer 260 and PWFM layer 250. In some embodiments, metal fill/bulk layer wraps NWFM layer 260 and/or PWFM layer 250. In some embodiments, gate electrode 80U and/or gate electrode 80L includes additional layers, such as a cap (e.g., a metal nitride cap and/or a silicon cap) and/or other gate layers.

The stacked device structure may thus include a CFET having a first GAA transistor (e.g., transistor 20U, such as an n-type transistor) over a second GAA transistor (e.g., transistor 20L, such as a p-type transistor). Gate electrodes of the first GAA transistor and the second GAA transistor may include different work function materials, and gate dielectrics of the first GAA transistor and the second GAA transistor may have the same and/or different compositions. For example, the first GAA transistor may include NWFM layer 260 (which is or forms a portion of gate electrode 80U) and a respective high-k dielectric layer 215 (which is or forms a portion of gate dielectric 78U), and the second GAA transistor may include PWFM layer 250 (which is or forms a portion of gate electrode 80L) and a respective high-k dielectric layer 215 (which is or forms a portion of gate dielectric 78L). In such example, the first GAA transistor may be an n-type transistor having a first threshold voltage, and the second GAA transistor may be a p-type transistor having a second threshold voltage different than the first threshold voltage.

By implementing the process described with reference to FIGS. 3A-3K, an interface IF between NWFM layer 260 and PWFM layer 250 is substantially free of metal oxide (e.g., metal oxide layer 252B). Because interface IF is substantially free of metal oxide, the disclosed CFETs (e.g., provided by device stack 12A and/or device stack 12B) exhibit lower gate resistance than CFETs having metal oxide layers between their gate stacks (e.g., between work function layers thereof). The disclosed CFETs thus exhibit improved performance, including improved threshold voltage control. In some embodiments, an oxygen content at the interface IF is less than about 5 atomic percent (at %). CFETs having oxygen contents greater than 5 at % at their upper gate/lower gate interfaces may exhibit gate resistance levels that are too high, and thus, negatively impact device performance. In some embodiments, because metal oxide layer 252B is removed by chorine-based gas treatment 255, a small amount of chlorine may be detected at interface IF between NWFM layer 260 and PWFM layer 250. For example, a chlorine content at interface IF is about 0 at % to about 2 at %. A chlorine content at interface IF of less than about 2 at % provides a stable threshold voltage (i.e., chlorine content less than about 2 at % does not and/or negligibly impacts threshold voltage). CFETs having chlorine contents greater than 2 at % at their upper gate/lower gate interfaces may undesirably shift and/or impact threshold voltage, and thus, negatively impact device performance. Different embodiments may have different advantages, and no particular advantage is required of any embodiment.

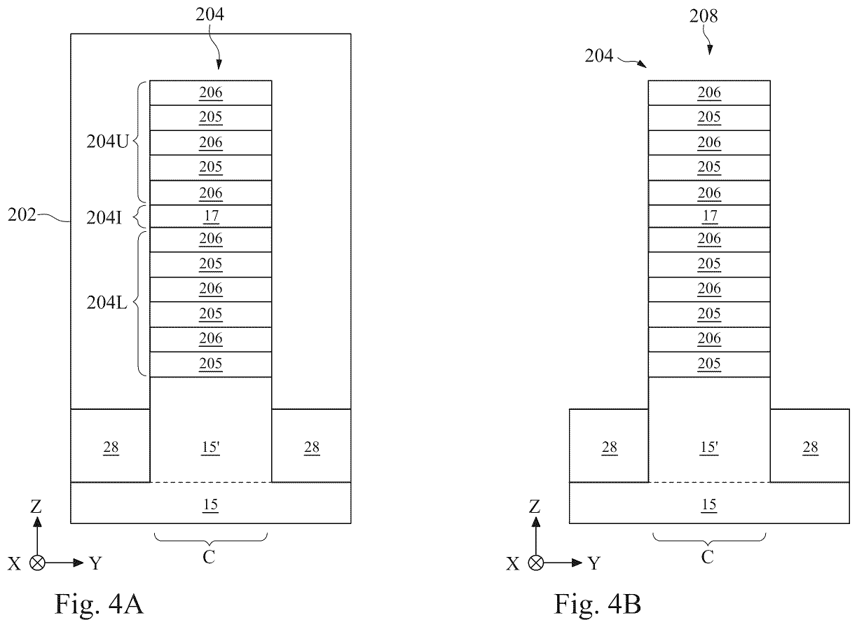

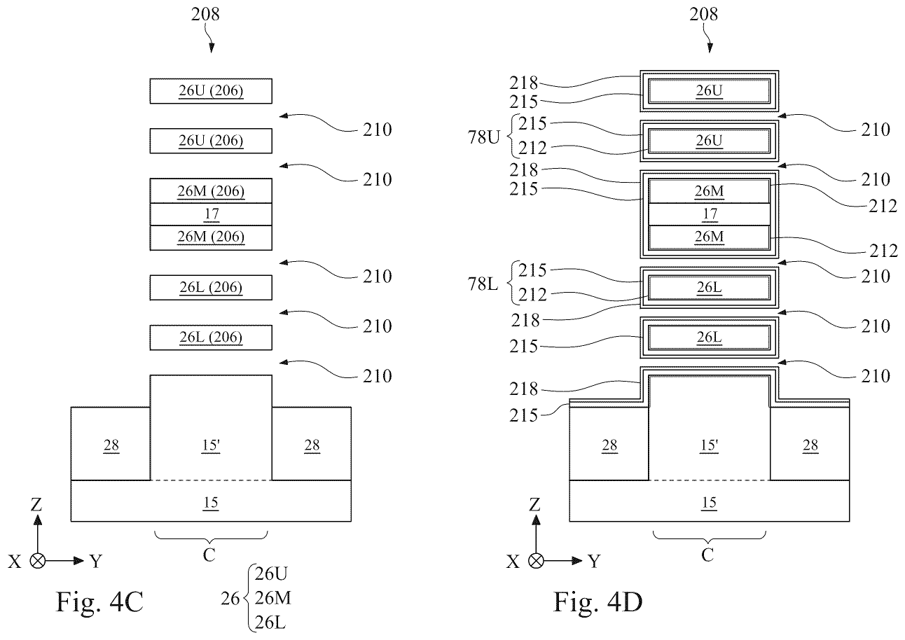

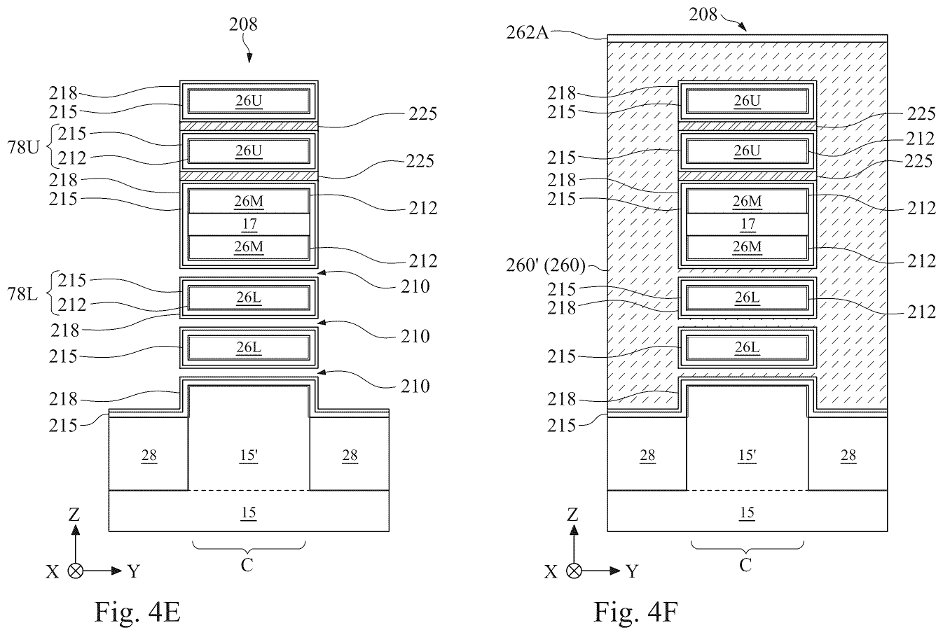

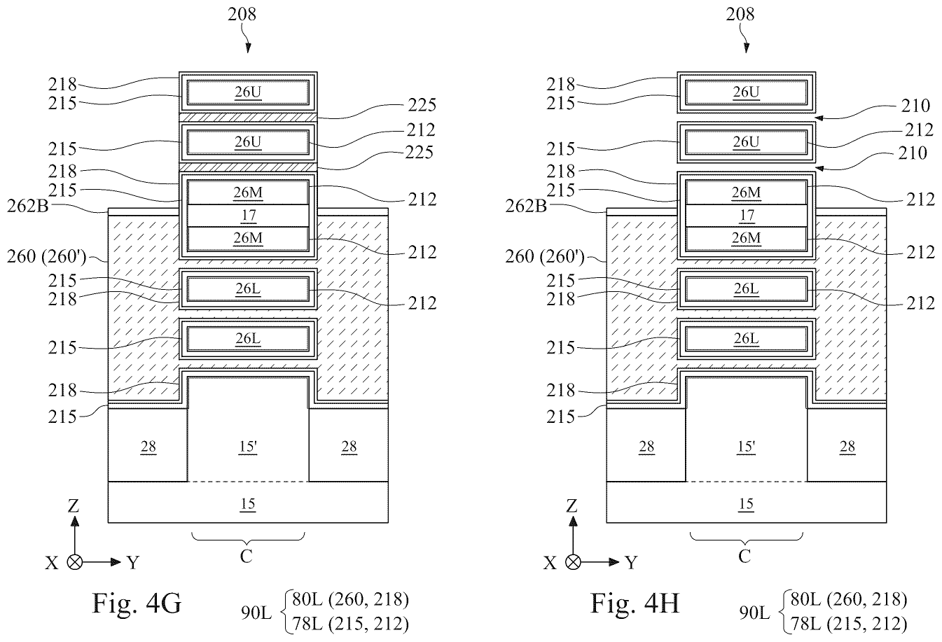

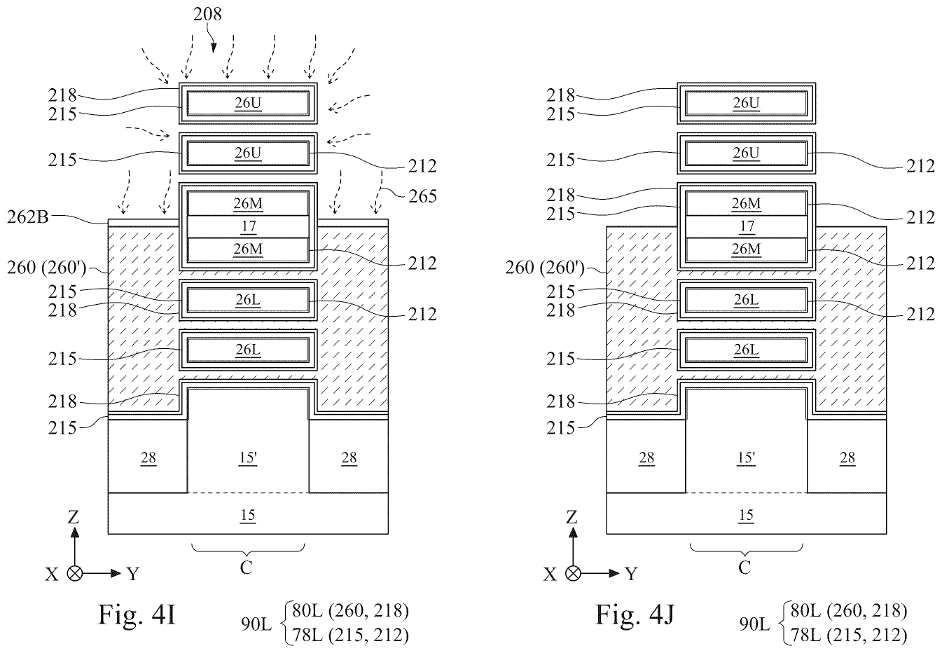

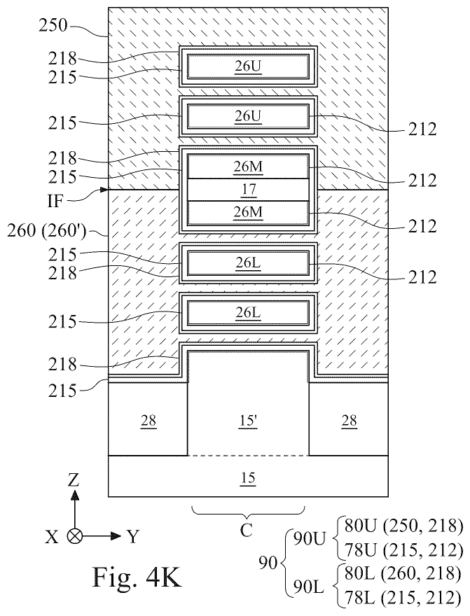

The present disclosure also contemplates embodiments where the process described above is implemented where the first GAA transistor (e.g., transistor 20U) is a p-type transistor and the second GAA transistor is an n-type transistor (e.g., transistor 20L), such as depicted in FIGS. 4A-4K. In such embodiments, the first GAA transistor may include PWFM layer 250 (which is or forms a portion of gate electrode 80U) and a respective high-k dielectric layer 215 (which is or forms a portion of gate dielectric 78U), and the second GAA transistor may include NWFM layer 260 (which is or forms a portion of gate electrode 80U) and a respective high-k dielectric layer 215 (which is or forms a portion of gate dielectric 78L). In such example, the first GAA transistor may be a p-type transistor having the second threshold voltage, and the second GAA transistor may be an n-type transistor having the first threshold voltage.

FIGS. 4A-4K are cross-sectional views of a stacked device structure, such as stacked device structure 10 of FIGS. 1A-1C, in portion or entirety, at various fabrication stages associated with method 100 of FIG. 2, according to various aspects of the present disclosure. Since the process flow illustrated in FIGS. 4A-4K is similar in many respects to the process flow illustrated in FIGS. 3A-3K, similar features are identified by the same reference numerals for clarity and simplicity. The cross-sectional views of FIGS. 4A-4K are taken (cut) along a gate lengthwise direction (e.g., a y-direction), like the cross-sectional view of FIG. 1B. FIGS. 4A-4K have been simplified for the sake of clarity to better understand the inventive concepts of the present disclosure. Additional features may be added in the stacked device structure of FIGS. 4A-4K, and some of the features described below can be replaced, modified, or eliminated in other embodiments of the stacked device structure of FIGS. 4A-4K.

Referring to FIGS. 4A-4E, fabrication of the stacked device structure may include forming a gate structure (e.g., dummy gate 202 and gate spacers 44 along sidewalls thereof) over a multilayer stack (e.g., multilayer stack 204) (FIG. 4A), such as described above with reference to FIG. 3A; removing a dummy gate (e.g., dummy gate 202) to form a gate opening (e.g., gate opening 208) (FIG. 4B), such as described above with reference to FIG. 3B; performing a channel release process to form an upper channel structure (e.g., semiconductor layers 26U) and a lower channel structure (e.g., semiconductor layers 26L) (FIG. 4C), such as described above with reference to FIG. 3C; forming interfacial layers (e.g., interfacial layers 212) over the upper channel structure and the lower channel structure (FIG. 4D), such as described above with reference to FIG. 3D; forming high-k dielectric layers (e.g., high-k dielectric layers 215) over the upper channel structure and the lower channel structure (FIG. 4D), such as described above with reference to FIG. 3D; forming high-k cap layers (e.g., high-k cap layers 218) over high-k dielectric layers (FIG. 4D), such as described above with reference to FIG. 3D; and forming dummy structures (e.g., dummy structures 225) in remainders of gaps (e.g., gaps 210) of the upper channel structure (FIG. 4E), such as described above with reference to FIG. 3E.

Referring to FIG. 4F and FIG. 4G, fabrication of the stacked device structure may further include forming a first type work function layer (e.g., NWFM layer 260) over the lower channel structure (FIG. 4F and FIG. 4G), such as described above with reference to FIG. 3F and FIG. 3G. In the depicted embodiment, NWFM layer 260, instead of PWFM layer 250, is formed over the lower channel structure, and NWFM layer 260 fills remainders of gaps 210 of the lower channel structure. In some embodiments, forming NWFM layer 260 may include depositing an NWFM material 260′ over the channel stack and recessing NWFM material 260′ below the upper channel structure (e.g., semiconductor layers 26U) in a manner similar to that described above with reference to PWFM material 250′ (FIG. 3F) and PWFM layer 250 (FIG. 3G). Further, in the depicted embodiment, due to differences in composition between PWFM layer 250 and NWFM layer 260, a metal oxide layer 262A may form over NWFM material 260′, and a metal oxide layer 262B may form over NWFM layer 260. In some embodiments, where NWFM material 260′ is titanium aluminum and NWFM layer 260 is a titanium aluminum layer, oxygen in the ambient may react with titanium, and metal oxide layer 262A and metal oxide layer 262B may be titanium aluminum oxide layers. Though metal oxide layer 262A is removed by recessing (e.g., etching back) of NWFM material 260′ to form NWFM layer 260, metal oxide layer 262B undesirably remains over NWFM layer 260 and between NWFM layer 260 and a subsequently formed gate layer (e.g., second type work function layer).

Accordingly, referring to FIG. 41 and FIG. 4J, metal oxide layer 262B and/or any metal oxide (and/or other native oxide) is removed from NWFM layer 260, such that a top surface of NWFM layer 260 (over which another metal gate layer is formed) is substantially free of oxygen. In some embodiments, a chlorine-based gas treatment 265 is performed to remove metal oxide layer 262B. Chlorine-based gas treatment 265 is similar to chlorine-based gas treatment 255 described above with reference to FIG. 3I and FIG. 3J, yet parameters thereof may be adjusted based on a composition of metal oxide layer 262B. Chlorine-based gas treatment 265 includes exposing metal oxide layer 262B to a chlorine-containing gas, which reacts with and/or breaks down metal oxide layer 262B until completely removed from NWFM layer 260. The chlorine-containing gas includes a transition metal and chlorine (i.e., a transition metal chloride), such as TaCl₅, TiCl₄, WCl₅, other transition metal chloride, or combinations thereof. In some embodiments, such as where NWFM layer 260 is a titanium aluminum layer and metal oxide layer 262B is a titanium aluminum oxide layer, gaseous (g) transition metal chloride (e.g., X—Cl, where X is a transition metal) may react with the titanium aluminum oxide layer (e.g., TiO₂ and Al₂O₃ thereof in solid forms) to provide gaseous transition metal oxychloride (e.g., XOCl), gaseous titanium oxychloride (e.g., TiOClₓ), and gaseous aluminum oxychloride (e.g., AlOClₓ), such as illustrated by the following reaction:

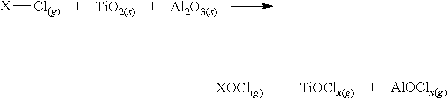

Parameters of the chlorine-based gas treatment 265 may be controlled to ensure complete removal of metal oxide layer 262B without (or negligibly) modifying NWFM layer 260 and high-k cap layers 218 (or high-k dielectric layers 215, such as in embodiments where high-k cap layers 218 are omitted), such as treatment temperature, a flow rate of the transition metal chloride, a flow rate of a carrier gas (e.g., an inert gas, such as helium, argon, nitrogen, xenon, other inert gas, or combinations thereof), treatment time, treatment pressure, other chlorine-based gas treatment parameters, or combinations thereof. In some embodiments, metal oxide layer 262B is removed by exposure to the chlorine-containing gas (e.g., gaseous transition metal chloride) without using a plasma. In some embodiments, chlorine-based gas treatment 265 may generate transition-metal-and-chlorine-containing plasma from the chlorine-containing gas (e.g., gaseous transition metal chloride), which removes metal oxide layer 262B.

Referring to FIG. 4K, fabrication of the stacked device structure may further include forming a second type work function layer (e.g., PWFM layer 250) over the upper channel structure, such as described above with reference to FIG. 4K. In the depicted embodiment, PWFM layer 250, instead of NWFM layer 260, is formed over the upper channel structure, and PWFM layer 250 fills remainders of gaps 210 of the upper channel structure. In some embodiments, forming PWFM layer 250 may include depositing PWFM material 250′ over NFWM layer 260 (e.g., over chlorine-treated surface thereof) and performing a planarization process in a manner similar to that described above with reference to NWFM material 260′ and FIG. 3K. To reduce/prevent exposure of NWFM layer 260 to oxygen ambient after removal of native oxide (e.g., metal oxide layer 262B) and thus reduce/prevent additional formation of native oxide, removal of metal oxide layer 262A and deposition of PWFM layer 250 are performed in-situ, such as described above with reference to FIG. 3K. For example, the stacked device structure remains under vacuum conditions during chlorine-based gas treatment 265 (i.e., native/metal oxide removal), deposition of NWFM layer 260, and therebetween. In some embodiments, chlorine-based gas treatment 265 and deposition of NWFM layer 260 are performed within a same process chamber and/or a same tool, such that the stacked device structure may remain under vacuum conditions during such processing.

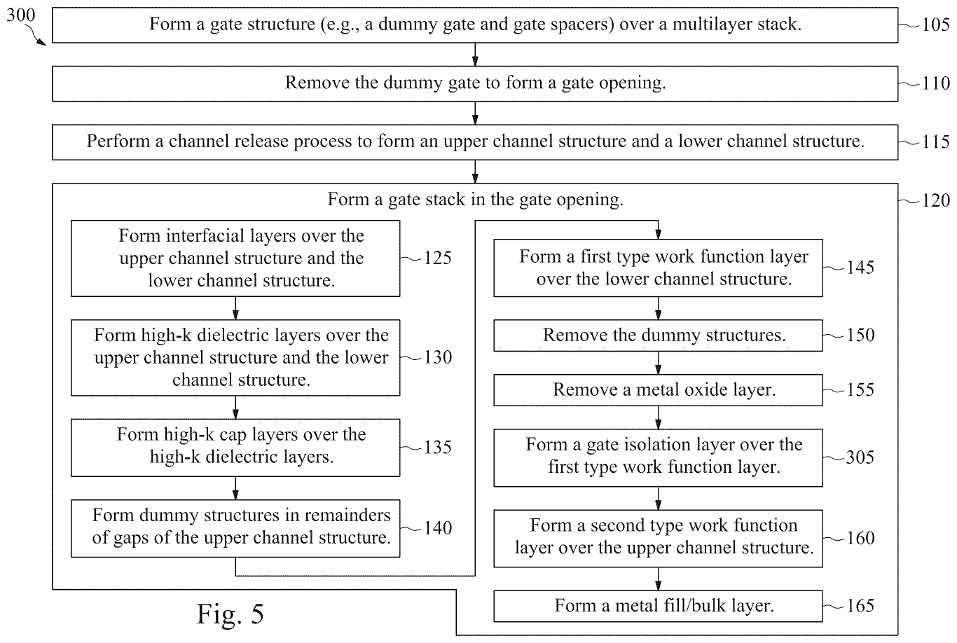

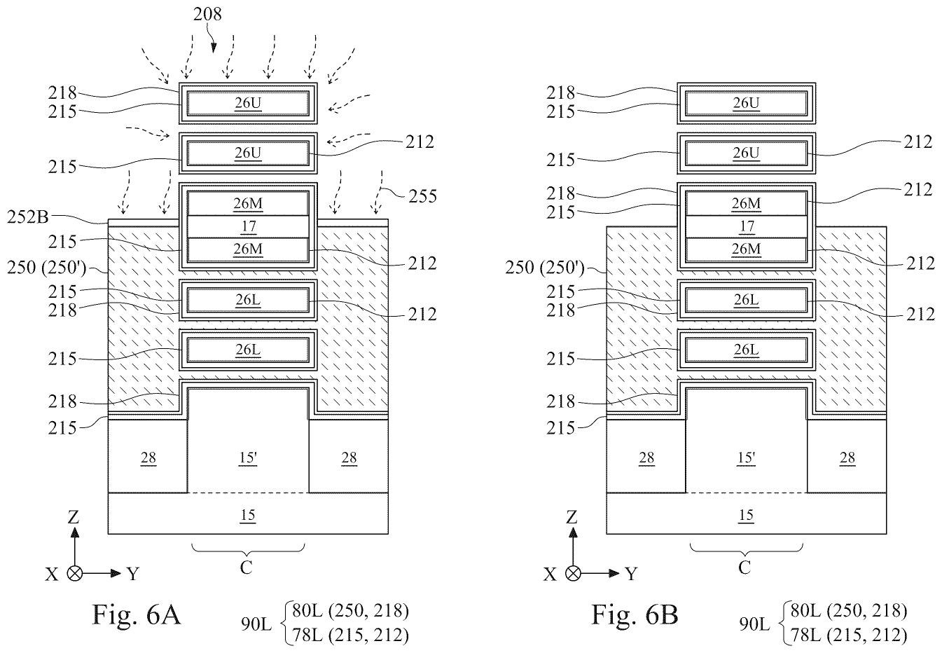

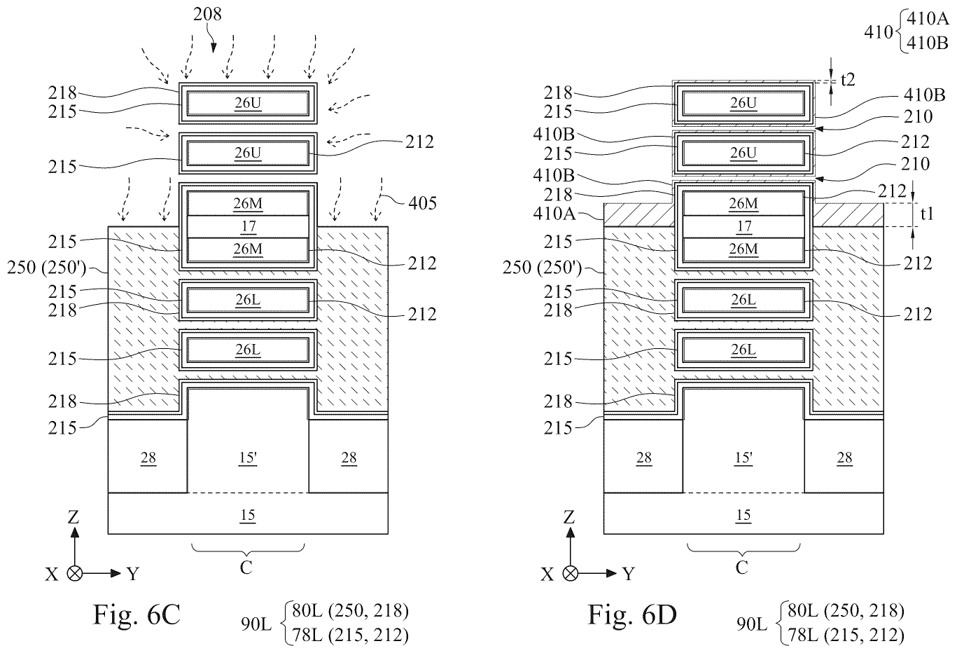

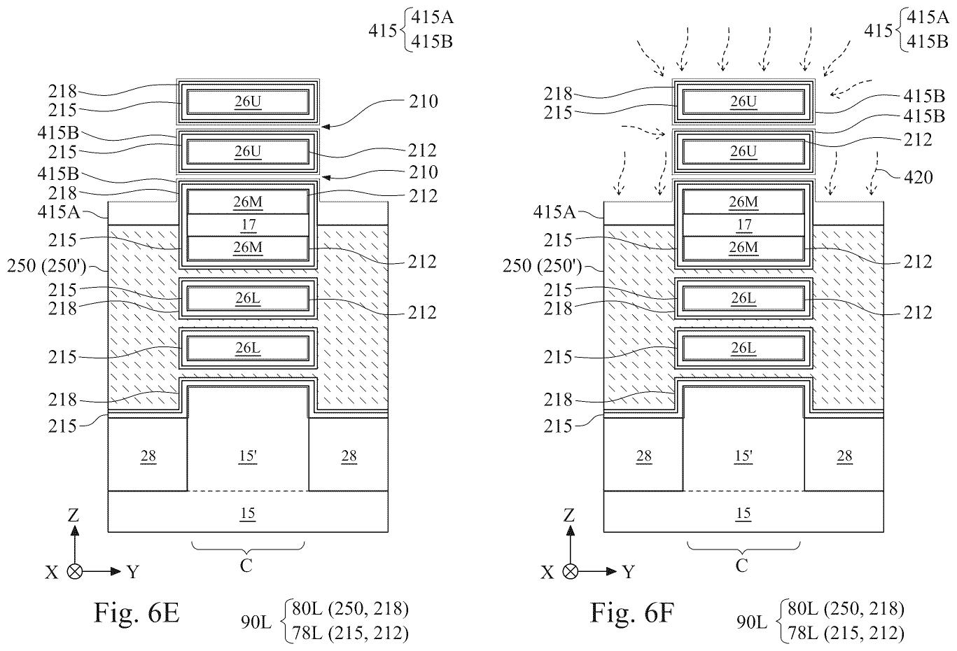

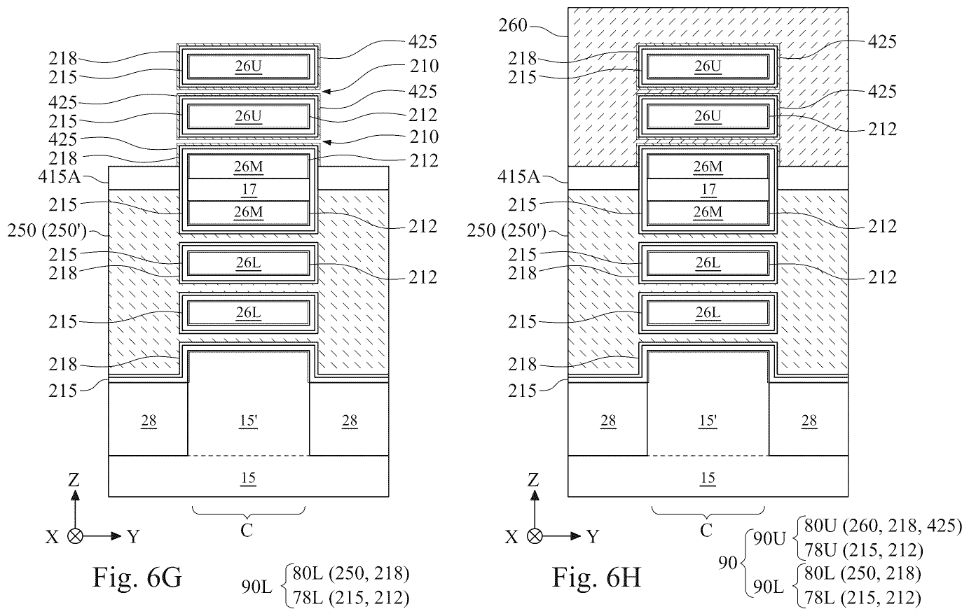

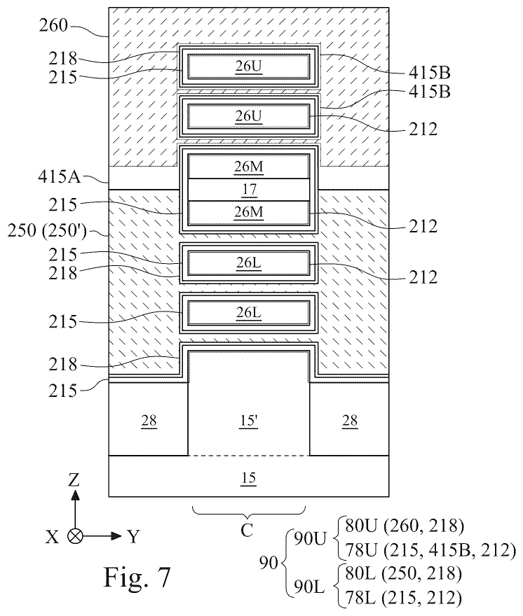

FIG. 5 is a flow chart of a method 300 for fabricating a gate stack of transistors of a transistor stack, such as gate 90 of a transistor stack of stacked device structure 10 of FIGS. 1A-1C, according to various aspects of the present disclosure. FIGS. 6A-6H are cross-sectional views of a stacked device structure, such as stacked device structure 10 of FIGS. 1A-IC, in portion or entirety, at various fabrication stages associated with method 300 of FIG. 5 according to various aspects of the present disclosure. FIG. 7 is a cross-sectional view of a stacked device structure, such as stacked device structure 10 of FIGS. 1A-IC, in portion or entirety, that may be fabricated according to method 300 of FIG. 5, according to various aspects of the present disclosure. Method 300 described with reference to FIGS. 6A-6H implements a native oxide removal process that eliminates and/or significantly reduces oxygen (e.g., metal oxide) at an interface of gate 90L and gate 90U, which may significantly reduce gate resistance and/or improve performance of stacked device structures. Method 300 described with reference to FIGS. 6A-6H also provides a self-aligned gate isolation layer between gate 90L and gate 90U (i.e., no patterning, such as a lithography and etching process is required to form the gate isolation layer). Method 300 is similar in many respects to method 100, and the process flow illustrated in FIGS. 6A-6H is similar in many respects to the process flow illustrated in FIGS. 3A-3K. Accordingly, similar features are identified by the same reference numerals for clarity and simplicity. The cross-sectional views of FIGS. 6A-6H and FIG. 7 are taken along a gate lengthwise direction, like the cross-sectional view of FIG. 1B. FIG. 5, FIGS. 6A-6H, and FIG. 7 have been simplified for the sake of clarity to better understand the inventive concepts of the present disclosure. Additional steps can be provided before, during, and after method 300, and some of the steps described can be moved, replaced, or eliminated for additional embodiments of method 300. Additional features may be added in the stacked device structures of FIGS. 6A-6H and FIG. 7, and some of the features described below can be replaced, modified, or eliminated in other embodiments of the stacked device structure of FIGS. 6A-6H and FIG. 7.

Referring to FIG. 5, method 300 may include forming a gate structure (e.g., dummy gate 202 and gate spacers 44 along sidewalls thereof) over a multilayer stack (e.g., multilayer stack 204) at block 105, such as described above with reference to FIG. 3A; removing a dummy gate (e.g., dummy gate 202) to form a gate opening (e.g., gate opening 208) at block 110, such as described above with reference to FIG. 3B; performing a channel release process to form an upper channel structure (e.g., semiconductor layers 26U) and a lower channel structure (e.g., semiconductor layers 26L) at block 115, such as described above with reference to FIG. 3C; forming interfacial layers (e.g., interfacial layers 212) over the upper channel structure and the lower channel structure at block 125, such as described above with reference to FIG. 3D; forming high-k dielectric layers (e.g., high-k dielectric layers 215) over the upper channel structure and the lower channel structure at block 130, such as described above with reference to FIG. 3D; forming high-k cap layers (e.g., high-k cap layers 218) over the high-k dielectric layers at block 135, such as described above with reference to FIG. 3D; forming dummy structures (e.g., dummy structures 225) in remainders of gaps (e.g., gaps 210) of the upper channel structure at block 140, such as described above with reference to FIG. 3E; forming a first type work function layer (e.g., PWFM layer 250) over the lower channel structure at block 145, such as described above with reference to FIG. 3F and FIG. 3G; and removing the dummy structures at block 150, such as described above with reference to FIG. 3H. Referring to FIG. 5, FIG. 6A, and FIG. 6B, the stacked device structure depicted in FIG. 6A has undergone processing associated with blocks 105-150 of method 300, and fabrication of the stacked device structure may further include removing a metal oxide layer (e.g., metal oxide layer 252B) at block 155, such as described above with reference to FIG. 3I and FIG. 3J. For example, chlorine-based gas treatment 255 may remove metal oxide layer 252B from PWFM layer 250.

Referring to FIG. 5 and FIGS. 6C-6E, method 300 further includes forming a gate isolation layer over the first type work function layer (e.g., PWFM layer 250) at block 305. For example, referring to FIG. 6C and FIG. 6D, the stacked device structure is exposed to an aluminum-based gas treatment 405 to form an aluminum-and-carbon containing layer 410A over PWFM layer 250. Aluminum-based gas treatment 405 includes exposing PWFM layer 250 to an aluminum-containing gas, which may react with PWFM layer 250. The aluminum-containing gas includes aluminum and carbon, such as Al(CH₃), Al(C₂H₅)₃, other aluminum-and-carbon containing precursor, or combinations thereof. In some embodiments, such as depicted, aluminum-based gas treatment 405 includes exposing high-k cap layers 218 (and/or high-k dielectric layers 215) over the upper channel structure to the aluminum-containing gas, which may react with high-k cap layers 218 (and/or high-k dielectric layers 215). Aluminum-based gas treatment 405 may thus also form aluminum-and-carbon containing layers 410B over high-k cap layers 218 (and/or high-k dielectric layers 215) disposed over the upper channel structure. Aluminum-and-carbon containing layer 410A and aluminum-and-carbon containing layers 410B may collectively be referred to as aluminum-and-carbon containing layer 410.

In some embodiments, aluminum-based gas treatment 405 is a deposition process. Because PWFM layer 250 and high-k cap layers 218 (and/or high-k dielectric layers 215) have different compositions, PWFM layer 250 and high-k cap layers 218 (and/or high-k dielectric layers 215) provide different deposition/growth surfaces. For example, a deposition/growth rate of an aluminum-and-carbon containing material on PWFM layer 250 (i.e., an oxygen-free surface, especially after subjected to chorine-based gas treatment 255) is greater than a deposition/growth rate of aluminum-and-carbon containing material on high-k cap layers 218 (and/or high-k dielectric layers 215) (i.e., oxygen-containing surfaces). The aluminum-and-carbon containing material thus deposits/grows faster on PWFM layer 250 than on high-k cap layers 218 (and/or high-k dielectric layers 215), such that a thickness t1 of aluminum-and-carbon containing layer 410A is greater than a thickness t2 of aluminum-and-carbon containing layers 410B. Further, the aluminum-and-carbon containing material may not deposit/grow on dielectric surfaces/materials that do not include metal, such as ILD layer 72U (e.g., a silicon-and-oxygen containing dielectric material) and/or CESL 70U (e.g., a dielectric material that includes silicon and oxygen, carbon, nitrogen, or combinations thereof). The present disclosure thus recognizes that, because aluminum-based gas treatment 405 may exhibit high deposition selectivity to oxide-free surfaces (e.g., PWFM layer 250), aluminum-based gas treatment 405 may be implemented to form a self-aligned gate isolation layer. In other words, aluminum-and-carbon containing layer 410 may be formed without masking portions of the stacked device structure, such that no additional patterning process is required by the disclosed process.

In some embodiments, aluminum-based gas treatment 405 is a selective CVD process that introduces an aluminum-and-carbon containing gas (e.g., Al(C₂H₅)₃) and a carrier gas (e.g., an inert gas, such as helium, argon, nitrogen, xenon, other inert gas, or combinations thereof) into a process chamber. The aluminum-and-carbon containing gas may interact with PWFM layer 250 and high-k cap layers 218 (and/or high-k dielectric layers 215) to form aluminum-and-carbon containing layer 410. Parameters of the aluminum-based gas treatment 405 may be controlled to provide and/or increase deposition/growth selectivity (i.e., faster deposition/growth of the aluminum-and-carbon containing material on PWFM layer 250 than on high-k cap layers 218 (and/or high-k dielectric layers 215)). Such parameters may include treatment temperature, a flow rate of the aluminum-containing gas, a flow rate of the carrier gas, treatment time, treatment pressure, treatment power (e.g., source power and/or radio frequency (RF) bias power), other aluminum-based gas treatment parameters, or combinations thereof.

Parameters of the aluminum-based gas treatment 405 may further be tuned to control thickness t1 and thickness t2. In some embodiments, thickness t1 is controlled to confine aluminum-and-carbon containing layer 410A below semiconductor layers 26U. For example, thickness t1 is less than a distance between a bottom of lower semiconductor layer 26U and a top of PWFM layer 250 (i.e., a top of aluminum-and-carbon containing layer 410A is below semiconductor layers 26U). In some embodiments, thickness t1 is no greater than a distance between a top of upper semiconductor layer 26M and a top of PWFM layer 250 (i.e., a top of aluminum-and-carbon containing layer 410A is at or below the top of upper semiconductor layer 26M). In the depicted embodiment, thickness t1 is less than the distance between the top of upper semiconductor layer 26M and the top of PWFM layer 250, such that the top of aluminum-and-carbon containing layer 410A is below the top of upper semiconductor layer 26M. In some embodiments, thickness t1 is greater than a thickness of isolation structure 17, but less than a total thickness of the intermediate structure. In some embodiments, thickness t2 is controlled to preserve gaps 210 of the upper channel structure (i.e., aluminum-and-carbon containing layers 410B partially, not completely, fill gaps 210). In some embodiments, thickness t2 is less than half of a distance (e.g., along the z-direction) between adjacent high-k cap layers 218 (or high-k dielectric layers 215) (i.e., half a remainder of gaps 210).

To reduce/prevent exposure of PWFM layer 250 to oxygen ambient after removal of native oxide (e.g., metal oxide layer 252B) and thus reduce/prevent additional formation of native oxide and/or preserve the oxide-free surfaces of PWFM 250 for deposition/growth of aluminum-and-carbon containing layer 410A thereover, removal of metal oxide layer 252B and deposition of aluminum-and-carbon containing layer 410 are performed in-situ. For example, the stacked device structure remains under vacuum conditions during chlorine-based gas treatment 255 (i.e., native/metal oxide removal), aluminum-based gas treatment 405, and therebetween. In some embodiments, chlorine-based gas treatment 255 and aluminum-based gas treatment 405 are performed within a same process chamber and/or a same tool, such that the stacked device structure may remain under vacuum conditions during such processing.

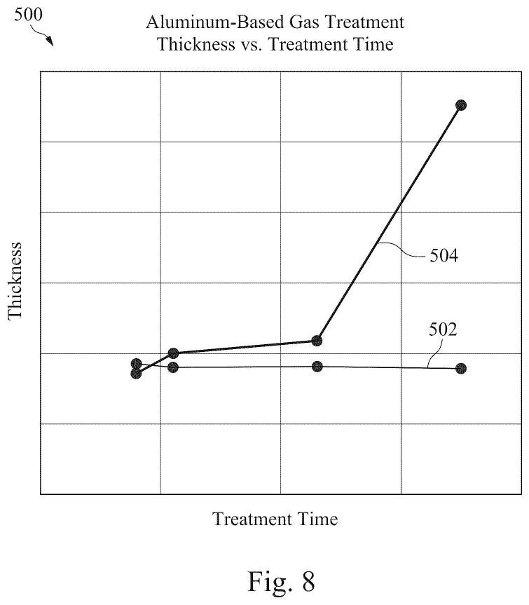

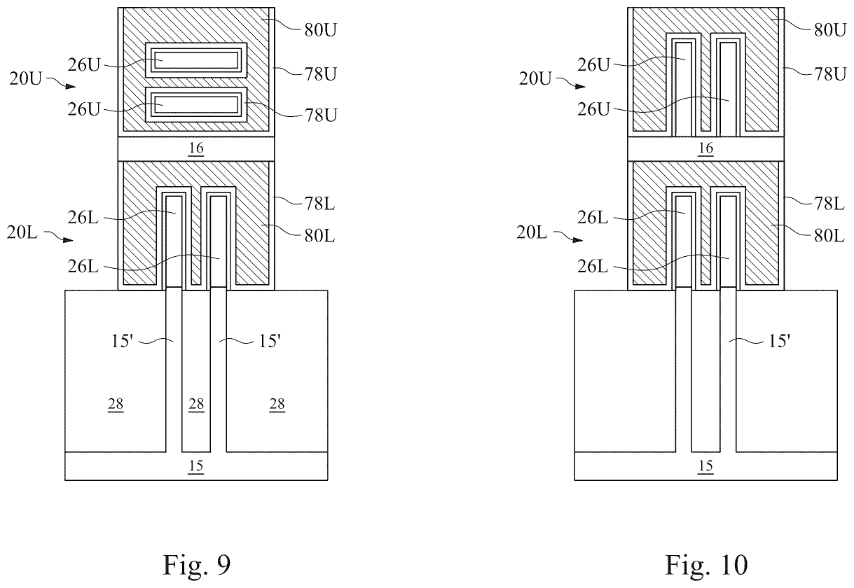

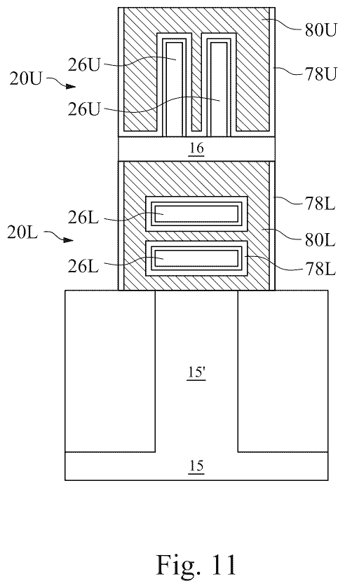

The present disclosure recognizes that performing chlorine-based gas treatment 255 and aluminum-based gas treatment 405 in-situ enhances deposition/growth of aluminum-and-carbon containing layer 410. Referring to FIG. 8, a plot 500 provides experimental results associated with depositing/growing aluminum-and-carbon containing layers on surfaces of PWFM layers (e.g., PWFM layer 250) using aluminum-based gas treatments, such as aluminum-based gas treatments that expose the surfaces of the PWFM layers to an aluminum-containing gas (e.g., triethylaluminum (TEA) (Al(C₂H₅)₃)). For example, plot 500 illustrates thicknesses of the aluminum-and-carbon containing layers as a function of treatment time, according to various aspects of the present disclosure. In plot 500, a line 502 corresponds with observed thicknesses of aluminum-and-carbon containing layers deposited/grown on PWFM surfaces (e.g., metal nitride surfaces, such a titanium nitride surfaces) in-situ. In other words, native oxide (e.g., metal oxide) is removed from the PWFM surfaces (e.g., by chlorine-based gas treatment 255) and the aluminum-and-carbon containing layers are deposited/grown on the PWFM layers (e.g., by aluminum-based gas treatment 405) without breaking vacuum. In contrast, a line 504 corresponds with observed thicknesses of aluminum-and-carbon containing layers deposited/grown on PWFM surfaces ex-situ. In other words, vacuum was broken between removing native oxide from the PWFM surfaces (e.g., by chlorine-based gas treatment 255) and depositing/growing the aluminum-and-carbon containing layers on the PWFM layers (e.g., by aluminum-based gas treatment 405). As evidenced by the experimental results, thicknesses of aluminum-and-carbon containing layers grown/deposited on the PWFM surfaces in-situ (line 502) are greater than thicknesses of aluminum-and-carbon containing layers grown/deposited on the PWFM surfaces ex-situ (line 504), particularly as treatment time increases.

Referring to FIG. 6E, the stacked device structure is exposed to an oxygen ambient (e.g., air), such that oxygen is incorporated into aluminum-and-carbon containing layer 410A, thereby forming an aluminum-oxygen-and-carbon containing layer 415A. Oxygen may also be incorporated into aluminum-and-carbon containing layers 410B, thereby forming aluminum-oxygen-and-carbon containing layers 415B. In some embodiments, vacuum is broken to expose the stacked device structure to the oxygen ambient. For example, when vacuum is broken, the stacked device structure is exposed to air (e.g., atmospheric oxygen). Aluminum-and-carbon containing layer 410 may adsorb oxygen from the oxygen ambient (e.g., air), and the adsorbed oxygen may bond with aluminum and/or carbon of aluminum-and-carbon containing layer 410. As aluminum-and-carbon containing layer 410 adsorbs oxygen, aluminum-and-carbon containing layer 410 may convert into an aluminum-oxygen-and-carbon containing layer 415, which collectively refers to aluminum-and-carbon containing layer 415A and aluminum-oxygen-and-carbon containing layers 415B. Aluminum-oxygen-and-carbon containing layer 415 (e.g., an AlOC layer) may include aluminum-oxygen bonds, aluminum-carbon bonds, aluminum-oxygen-carbon bonds, carbon-oxygen bonds, or combinations thereof.

Referring to FIG. 6F and FIG. 6G, in some embodiments, the stacked device structure is exposed to a reduction gas treatment 420, for example, to convert aluminum-oxygen-and-carbon containing layers 415B into aluminum layers 425. Reduction gas treatment 420 may remove oxygen and/or carbon constituents from aluminum-oxygen-and-carbon containing layers 415B. In some embodiments, reduction gas treatment 420 includes exposing aluminum-oxygen-and-carbon containing layers 415B to a hydrogen-containing gas, which may react with aluminum-oxygen-and-carbon containing layers 415B to remove oxygen and carbon therefrom. The hydrogen-containing gas includes hydrogen, such as H₂ and/or other hydrogen-containing precursor. In some embodiments, where reduction gas treatment 420 is a hydrogen gas treatment (e.g., an H₂ treatment), gaseous hydrogen (e.g., H₂) may react with aluminum-oxygen-and-carbon containing layers 415B (e.g., AlOC in solid form) to provide water vapor (e.g., gaseous H₂O), gaseous hydrocarbon (e.g., CHₓ), and aluminum layers 425 (e.g., Al in solid form), such as illustrated by the following reaction:

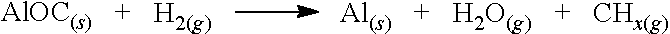

Parameters of reduction gas treatment 420 may be controlled to ensure conversion of aluminum-oxygen-and-carbon containing layers 415B into aluminum layers 425, such as treatment temperature, a flow rate of the hydrogen-containing gas (e.g., H₂), a flow rate of a carrier gas (e.g., an inert gas, such as helium, argon, nitrogen, xenon, other inert gas, or combinations thereof), treatment time, treatment pressure, other reduction gas treatment parameters, or combinations thereof. In some embodiments, such as depicted, reduction gas treatment 420 may not react (or negligibly react) with aluminum-oxygen-and-carbon containing layer 415A, such that aluminum-oxygen-and-carbon containing layer 415A remains after reduction gas treatment 420. In other words, reduction gas treatment 420 does not convert aluminum-oxygen-and-carbon containing layer 415A, or portion thereof, into an aluminum layer. In some embodiments, reduction gas treatment 420 may react with and convert a top portion of aluminum-oxygen-and-carbon containing layer 415A into an aluminum layer. In such embodiments, a thin aluminum layer may be disposed on aluminum-oxygen-and-carbon containing layer 415A.

Conversion of aluminum-oxygen-and-carbon containing layers 415B, but not aluminum-oxygen-and-carbon containing layer 415A, into aluminum layers 425 may result from tuning of parameters of reduction gas treatment 420 and/or differences in compositions. In some embodiments, a carbon content of aluminum-oxygen-and-carbon containing layer 415A is greater than a carbon content of aluminum-oxygen-and-carbon containing layers 415B, and a resistance of carbon-rich aluminum-oxygen-and-carbon containing layer 415A (e.g., a carbon-rich AlOC layer) to reduction gas treatment 420 may be greater than a resistance of aluminum-oxygen-and-carbon containing layers 415B to reduction gas treatment 420. For example, gaseous hydrogen (e.g., H₂) may react more readily and/or quicker with aluminum-oxygen-and-carbon containing layers 415B to form water vapor (e.g., gaseous H₂O) and gaseous hydrocarbon (e.g., CHₓ) when compared to such reaction(s) with carbon-rich aluminum-oxygen-and-carbon containing layer 415A. In some embodiments, an oxygen content of aluminum-oxygen-and-carbon containing layers 415B is greater than an oxygen content of aluminum-oxygen-and-carbon containing layer 415A, and a resistance of oxygen-rich aluminum-oxygen-and-carbon containing layers 415B is less than a resistance of aluminum-oxygen-and-carbon containing layer 415A to reduction gas treatment 420. For example, gaseous hydrogen may react more readily and/or quicker with oxygen-rich aluminum-oxygen-and-carbon containing layers 415B to form water vapor and gaseous hydrocarbon when compared to such reaction(s) with aluminum-oxygen-and-carbon containing layer 415A. The differences in carbon content and/or oxygen content may result from different deposition/growth surfaces (i.e., PWFM layer 250 and high-k cap layers 218 (and/or high-k dielectric layers 215)). In some embodiments, a carbon content of aluminum-and-carbon containing layer 410A is greater than a carbon content of aluminum-and-carbon containing layers 410B (FIG. 6C, FIG. 6D).

Referring to FIG. 5 and FIG. 6H, method 300 includes forming a second type work function layer (e.g., NWFM layer 260) over the upper channel structure at block 160, such as described above with reference to FIG. 3K. For example, NWFM layer 260 is formed over aluminum-oxygen-and-carbon containing layer 415A and aluminum layers 425, and NWFM layer 260 may fill remainders of gaps 210, such as those remaining between portions of aluminum layers 425 between semiconductor layers 26 of the upper channel structure. In such embodiments, aluminum layers 425 are between NWFM layer 260 and high-k cap layers 218 (and/or high-k dielectric layers 215), and aluminum layers 425 may form a portion of gate electrode 80U. Further, in such embodiments, aluminum-oxygen-and-carbon containing layer 415A is between NWFM layer 260 and PWFM layer 250, and aluminum-oxygen-and-carbon containing layer 415A may function as a barrier layer and/or an isolation layer between different type metal gates (i.e., NWFM layer 260 and PWFM layer 250) of gate 90. Aluminum-oxygen-and-carbon containing layer 415A may thus be referred to as a gate isolation layer. In some embodiments, aluminum-oxygen-and-carbon containing layer 415A may inhibit constituents (e.g., aluminum) of NWFM layer 260 from diffusing into PWFM layer 250 and/or inhibit constituents of PWFM layer 250 from diffusing into NWFM layer 260. In some embodiments, method 300 may further include forming a metal fill/bulk layer at block 165.

In some embodiments, conversion of aluminum-oxygen-and-carbon containing layers 415B into aluminum layers 425 and deposition of NWFM layer 260 are performed in-situ. For example, the stacked device structure remains under vacuum conditions during reduction gas treatment 420, deposition of NWFM layer 260, and therebetween. In some embodiments, reduction gas treatment 420 and deposition of NWFM layer 260 (e.g., by CVD or ALD) are performed within a same process chamber and/or a same tool, such that the stacked device structure may remain under vacuum conditions during such processing. In contrast, formation of aluminum-and-carbon containing layer 410 and deposition of NWFM layer 260 are performed ex-situ. In other words, vacuum is broken between aluminum-based gas treatment 255 and deposition of NWFM layer 260, thereby resulting in the conversion of aluminum-and-carbon containing layer 410 into aluminum-oxygen-and-carbon containing layer 415.

Referring to FIG. 7, in some embodiments, fabrication of the stacked device structure may omit processing associated with FIG. 6F and FIG. 6G, and aluminum-oxygen-and-carbon containing layers 415B are not converted into aluminum layers 425. In such embodiments, NWFM layer 260 is formed over aluminum-oxygen-and-carbon containing layers 415B, instead of aluminum layers 425, and NWFM layer 260 may fill remainders of gaps 210, such as those remaining between portions of aluminum-oxygen-and-carbon containing layers 415B between semiconductor layers 26 of the upper channel structure. In such embodiments, aluminum-oxygen-and-carbon containing layers 415B are between NWFM layer 260 and high-k cap layers 218 (and/or high-k dielectric layers 215), and aluminum-oxygen-and-carbon containing layers 415B may form a portion of gate dielectric 78U. Accordingly, gate dielectric 78U may include aluminum-oxygen-and-carbon containing layers 415B and high-k dielectric layers 215, while gate dielectric 78L includes only high-k dielectric layers 215.

Devices and/or structures described herein, such as stacked device structure 10, device stack 12A, device stack 12B, device 14U, device 14L, transistor 20U, transistor 20L, other stacked device structures, etc. may be included in a microprocessor, a memory, other IC device, or combinations thereof. In some embodiments, stacked device structure 10 and/or other stacked device structure described herein is a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor transistors, bipolar junction transistors (BJTs), laterally diffused MOS (LDMOS) transistors, high voltage transistors, high frequency transistors, other components, or combinations thereof.

The present disclosure provides for many different embodiments. Gate stack (e.g., high-k/metal gate) fabrication methods are described herein and provide numerous advantages, particularly for stacked device structures. The gate stacks disclosed herein may be implemented in a variety of device types. For example, the gate stacks described herein are suitable for stacked planar field-effect transistors (FETs), stacked multigate transistors, such as stacked FinFETs, stacked GAA transistors, stacked fork-sheet devices, stacked omega-gate (Ω-gate) devices, stacked pi-gate (Π-gate) devices, or combinations thereof. In the embodiments described above, the gate stacks described herein are implemented in stacked GAA transistors. Referring to FIG. 9, in some embodiments, the gate stacks described herein may be implemented in stacked device structures that include upper GAA transistors (e.g., transistors 20U of device 14U) disposed over lower FinFET transistors (e.g., transistors 20L of device 14L). In such embodiments, semiconductor layers 26L are semiconductor fins extending from substrate 15 (15′), and semiconductor layers 26U are suspended over substrate 15 and/or isolation structure 16 (e.g., semiconductor layers 26U may be nanosheets, nanowires, or the like). Referring to FIG. 10, in some embodiments, the gate stacks described herein may be implemented in stacked device structures that include upper FinFET transistors (e.g., transistors 20U of device 14U) disposed over lower FinFET transistors (e.g., transistors 20L of device 14L). In such embodiments, semiconductor layers 26L are semiconductor fins extending from substrate 15 (15′), and semiconductor layers 26U are semiconductor fins extending from isolation structure 16. Referring to FIG. 11, in some embodiments, the gate stacks described herein may be implemented in stacked device structures that include upper FinFET transistors (e.g., transistors 20U of device 14U) disposed over lower GAA transistors (e.g., transistors 20L of device 14L). In such embodiments, semiconductor layers 26U are semiconductor fins extending from isolation structure 16, and semiconductor layers 26L are suspended (e.g., semiconductor layers 26L may be nanosheets, nanowires, or the like).

An exemplary method includes forming a semiconductor layer stack over a substrate. The semiconductor layer stack includes a first semiconductor layer disposed over a second semiconductor layer. The method further includes forming a first type metal gate layer around the second semiconductor layer. The method further includes, after removing a native oxide layer from over the first type metal gate layer, forming a second type metal gate layer over the first type metal gate layer. The second type metal gate layer is formed around the first semiconductor layer. In some embodiments, removing the native oxide layer from over the first type metal gate layer includes performing a chlorine-based gas treatment. In some embodiments, the native oxide layer is a metal oxide layer, and performing the chlorine-based gas treatment includes exposing the native oxide layer to a metal-and-chlorine-containing gas. In some embodiments, forming the first type metal gate layer around the second semiconductor layer includes depositing a first type metal gate material over the second semiconductor layer and the first semiconductor layer and etching back the first type metal gate material, such that the first type metal gate material is removed from over the first semiconductor layer.

In some embodiments, the method further includes performing removing the native oxide layer and forming the second type metal gate layer in-situ. In some embodiments, the method further includes forming an aluminum-containing isolation layer over the first type metal gate layer after removing the native oxide layer from over the first type metal gate layer and before forming the second type metal gate layer. In some embodiments, the method further includes performing removing the native oxide layer and forming the aluminum-containing isolation layer in-situ. In some embodiments, forming the aluminum-containing isolation layer over the first type metal gate layer includes performing an aluminum-based gas treatment under vacuum and breaking vacuum after the aluminum-based gas treatment.

Another exemplary method includes forming a semiconductor layer stack over a substrate. The semiconductor layer stack includes a first semiconductor layer disposed over a second semiconductor layer. The method further includes forming a first type metal gate layer around the second semiconductor layer. The method further includes, after forming an aluminum-containing isolation layer over the first type metal gate layer, forming a second type metal gate layer around the first semiconductor layer and over the aluminum-containing isolation layer. In some embodiments, the method further includes removing a native metal oxide layer from over the first type metal gate layer before forming the aluminum-containing isolation layer. In some embodiments, removing the native metal oxide layer from over the first type metal gate layer includes performing a chlorine-based gas treatment.

In some embodiments, forming the aluminum-containing isolation layer over the first type metal gate layer includes performing an aluminum-based gas treatment to form an aluminum-and-carbon containing material over the first type metal gate layer. In some embodiments, forming the aluminum-containing isolation layer over the first type metal gate layer further includes exposing the aluminum-and-carbon containing material to an oxygen-containing ambient. In some embodiments, the method further includes performing a reduction gas treatment after exposing the aluminum-and-carbon containing material to the oxygen-containing ambient and before forming the second type metal gate layer around the first semiconductor layer. In some embodiments, performing the reduction gas treatment includes performing a hydrogen-based gas treatment. In some embodiments, performing the reduction gas treatment and forming the second type metal gate layer are performed in-situ.

An exemplary stacked device structure includes a semiconductor layer stack disposed over a substrate. The semiconductor layer stack includes a first semiconductor layer disposed over a second semiconductor layer. The stacked device structure further includes a gate. The gate includes a first gate dielectric layer and a second gate dielectric layer. The first gate dielectric layer is disposed over the first semiconductor layer, and the second gate dielectric layer is disposed over the second semiconductor layer. The gate further includes a first type work function metal layer and a second type work function metal layer. The first type work function metal layer is disposed over the first gate dielectric layer, and the second type work function metal layer is disposed over the second gate dielectric layer. The gate further includes an aluminum-carbon-and-oxygen containing layer disposed between the first type work function metal layer and the second type work function metal layer. In some embodiments, the gate further includes an aluminum layer disposed between the first type work function metal layer and the first gate dielectric layer. In some embodiments, the aluminum-carbon-and-oxygen containing layer is a first aluminum-carbon-and-oxygen containing layer, and the gate further includes a second aluminum-carbon-and-oxygen containing layer disposed between the first type work function metal layer and the first gate dielectric layer. In some embodiments, the first gate dielectric layer includes a first high-k dielectric layer, and the second gate dielectric layer includes a second high-k dielectric layer. In some embodiments, the gate further includes a first high-k cap layer and a second high-k cap layer. The first high-k cap layer may be disposed between the first high-k dielectric layer and the first type work function metal layer, and the second high-k cap layer may be disposed between the second high-k dielectric layer and the second type work function metal layer.

An exemplary gate stack may include a first gate stack over a first semiconductor layer (e.g., a first nanostructure, such as a first nanosheet, a first nanowire, a first nanorod, etc.) and a second gate stack over a second semiconductor layer (e.g., a second nanostructure, such as a second nanosheet, a second nanowire, a second nanorod, etc.). The first semiconductor layer may be disposed over the second semiconductor layer, and the first semiconductor layer and the second semiconductor layer may form a semiconductor layer stack of a stacked device structure. The first gate stack may include a first gate dielectric and a first gate electrode, which may include a first type metal gate layer. The first gate stack may include a second gate dielectric and a second gate electrode, which may include a second type metal gate layer. The first type metal gate layer may be disposed over the second type metal gate layer. The first type metal gate layer and the second type metal gate layer may be of opposite type, such as an n-type work function metal (NWFM) layer and a p-type work function metal (PWFM) layer, respectively.

An exemplary method for forming the gate stack may include depositing the second type metal gate layer over the second semiconductor layer and the first semiconductor layer, removing the second type metal gate layer from over the first semiconductor layer (e.g., by etching back), and depositing the first type metal gate layer over the first semiconductor layer and the second type metal gate layer. The first gate dielectric and the second gate dielectric may be formed over the first semiconductor layer and the second semiconductor layer, respectively, before depositing the second type metal gate layer. In some embodiments, a dummy material (e.g. a dielectric material) may be formed between the first semiconductor layer and other device features (e.g., other first semiconductor layers) before depositing the second type metal gate layer, and the dummy material may be removed after removing the second type metal gate layer from over the first semiconductor layer (e.g., by selectively etching thereof).

A native oxide (e.g., metal oxide) may form over the second type metal gate layer before depositing the first type metal gate layer, such that the native oxide is between the second type metal gate layer and the first type metal gate layer. Such native oxide may undesirably cause and/or increase gate resistance. In some embodiments, the present disclosure thus proposes performing a chlorine-based gas treatment to remove the native oxide before depositing the first type metal gate layer over the first semiconductor layer and the second type metal gate layer. In some embodiments, the chorine-based gas treatment exposes the native oxide to transition metal chlorides, such as TaCl₅, TiCl₄, WCl₅, or combinations thereof. To reduce/prevent exposure of the second type metal gate layer to oxygen ambient after removal of the native oxide (and thus reduce/prevent formation of native oxide), the chlorine-based gas treatment may be performed in-situ with the depositing of the first type metal gate layer.

In some embodiments, to enhance device performance, the present disclosure proposes forming an aluminum-containing isolation structure over the second type metal gate layer before depositing the first type metal gate layer. In some embodiments, forming the aluminum-containing isolation structure includes performing an aluminum-based gas treatment to form an aluminum-and-carbon-containing layer over the second type metal and exposing the aluminum-and-carbon-containing layer to an oxygen ambient (e.g., air), such that oxygen is incorporated into the aluminum-and-carbon-containing layer, thereby providing an aluminum-oxygen-and-carbon-containing layer. In some embodiments, where the native oxide is removed before forming the aluminum-containing isolation structure, the chlorine-based gas treatment and the aluminum-based gas treatment may be performed in-situ (e.g., without breaking vacuum), while the aluminum-based gas treatment may be performed ex-situ with the depositing of the first type metal gate layer (e.g., vacuum is broken between such steps).

In some embodiments, the aluminum-and-carbon-containing layer, and thus the aluminum-oxygen-and-carbon-containing layer, may also form over the first semiconductor layer and/or the first gate dielectric. In such embodiments, because a first portion of the aluminum-and-carbon-containing layer is formed over an oxygen-free surface (e.g., second type metal gate layer) and a second portion of the aluminum-and-carbon-containing layer is formed over an oxygen-containing surface (e.g., the first gate dielectric), a thickness of a first portion of the aluminum-oxygen-and-carbon-containing layer over the second type metal gate layer may be greater than a thickness of a second portion of the aluminum-oxygen-and-carbon-containing layer over the first gate dielectric. In some embodiments, a composition of the first portion of the aluminum-oxygen-and-carbon-containing layer over the second type metal gate layer may be different than a composition of the second portion of the aluminum-oxygen-and-carbon-containing layer over the first gate dielectric. For example, a carbon content of the first portion of the aluminum-oxygen-and-carbon-containing layer over the second type metal gate layer may be greater than a carbon content of the second portion of the aluminum-oxygen-and-carbon-containing layer over the first gate dielectric. In some embodiments, a reduction gas treatment may be performed to convert the second portion of the aluminum-oxygen-and-carbon-containing layer into an aluminum layer. In some embodiments, the reduction gas treatment may be performed in-situ with the depositing of the first type metal gate layer. In some embodiments, the reduction gas treatment is a hydrogen gas treatment (e.g., an H₂ treatment).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor layer stack over a substrate, wherein the semiconductor layer stack includes a first semiconductor layer disposed over a second semiconductor layer;
forming a first type metal gate layer around the second semiconductor layer; and
after removing a native oxide layer from over the first type metal gate layer, forming a second type metal gate layer over the first type metal gate layer, wherein the second type metal gate layer is formed around the first semiconductor layer.

2. The method of claim 1, wherein the removing the native oxide layer from over the first type metal gate layer includes performing a chlorine-based gas treatment.

3. The method of claim 2, wherein the native oxide layer is a metal oxide layer, and the performing the chlorine-based gas treatment includes exposing the native oxide layer to a metal-and-chlorine-containing gas.

4. The method of claim 1, further comprising performing the removing the native oxide layer and the forming the second type metal gate layer in-situ.

5. The method of claim 1, further comprising forming an aluminum-containing isolation layer over the first type metal gate layer after removing the native oxide layer from over the first type metal gate layer and before forming the second type metal gate layer.

6. The method of claim 5, further comprising performing the removing the native oxide layer and the forming the aluminum-containing isolation layer in-situ.

7. The method of claim 5, wherein the forming the aluminum-containing isolation layer over the first type metal gate layer includes:
performing an aluminum-based gas treatment under vacuum; and
breaking vacuum after the aluminum-based gas treatment.

8. The method of claim 1, wherein the forming the first type metal gate layer around the second semiconductor layer includes:
depositing a first type metal gate material over the second semiconductor layer and the first semiconductor layer; and
etching back the first type metal gate material, such that the first type metal gate material is removed from over the first semiconductor layer.

9. A method comprising:
forming a semiconductor layer stack over a substrate, wherein the semiconductor layer stack includes a first semiconductor layer disposed over a second semiconductor layer;
forming a first type metal gate layer around the second semiconductor layer; and
after forming an aluminum-containing isolation layer over the first type metal gate layer, forming a second type metal gate layer around the first semiconductor layer and over the aluminum-containing isolation layer.

10. The method of claim 9, wherein the forming the aluminum-containing isolation layer over the first type metal gate layer includes performing an aluminum-based gas treatment to form an aluminum-and-carbon containing material over the first type metal gate layer.

11. The method of claim 10, wherein the forming the aluminum-containing isolation layer over the first type metal gate layer further includes exposing the aluminum-and-carbon containing material to an oxygen-containing ambient.

12. The method of claim 11, further comprising performing a reduction gas treatment after exposing the aluminum-and-carbon containing material to the oxygen-containing ambient and before forming the second type metal gate layer around the first semiconductor layer.

13. The method of claim 12, wherein the performing the reduction gas treatment includes performing a hydrogen-based gas treatment.

14. The method of claim 12, wherein the performing the reduction gas treatment and the forming the second type metal gate layer are performed in-situ.

15. The method of claim 9, further comprising removing a native metal oxide layer from over the first type metal gate layer before forming the aluminum-containing isolation layer.

16. The method of claim 15, wherein the removing the native metal oxide layer from over the first type metal gate layer includes performing a chlorine-based gas treatment.

17. A stacked device structure comprising:
a semiconductor layer stack disposed over a substrate, wherein the semiconductor layer stack includes a first semiconductor layer disposed over a second semiconductor layer; and
a gate that includes:
a first gate dielectric layer and a second gate dielectric layer, wherein the first gate dielectric layer is disposed over the first semiconductor layer and the second gate dielectric layer is disposed over the second semiconductor layer,
a first type work function metal layer and a second type work function metal layer, wherein the first type work function metal layer is disposed over the first gate dielectric layer and the second type work function metal layer is disposed over the second gate dielectric layer, and
an aluminum-carbon-and-oxygen containing layer disposed between the first type work function metal layer and the second type work function metal layer.

18. The stacked device structure of claim 17, wherein the gate includes an aluminum layer disposed between the first type work function metal layer and the first gate dielectric layer.

19. The stacked device structure of claim 17, wherein the aluminum-carbon-and-oxygen containing layer is a first aluminum-carbon-and-oxygen containing layer, and the gate includes a second aluminum-carbon-and-oxygen containing layer disposed between the first type work function metal layer and the first gate dielectric layer.

20. The stacked device structure of claim 17, wherein:
the first gate dielectric layer includes a first high-k dielectric layer;
the second gate dielectric layer includes a second high-k dielectric layer; and
the gate further includes a first high-k cap layer and a second high-k cap layer, wherein the first high-k cap layer is disposed between the first high-k dielectric layer and the first type work function metal layer and the second high-k cap layer is disposed between the second high-k dielectric layer and the second type work function metal layer.
